(19) United States
(12) Patent Application Publication
(10) Pub. No.: US 2025/0255073 A1
(43) Pub. Date: Aug. 7, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: JUNGHWAN YI, Yongin-si (KR); SOODONG KIM, Yongin-si (KR); YUNHA RYU, Yongin-si (KR)

(21) Appl. No.: 18/980,707

(22) Filed: Dec. 13, 2024

(30) Foreign Application Priority Data
Feb. 6, 2024 (KR) 10-2024-0018328

(51) Int. Cl. H10H 29/80; H10H 29/01; H10H 29/37; H10K 59/12; H10K 59/122

(52) U.S. Cl. CPC H10H 29/8321; H10H 29/012; H10H 29/37; H10K 59/1201; H10K 59/122

(57) ABSTRACT

A display device includes a first electrode above a substrate, a second electrode above the substrate, and spaced apart from the first electrode in a first direction, an inorganic light-emitting element in a first auxiliary pixel area, above the first electrode, and connected to the first electrode, an organic light-emitting layer above the substrate, in a second auxiliary pixel area spaced apart from the first auxiliary pixel area in the first direction, and covering the second electrode, and a third electrode above the organic light-emitting layer.

### CROSS-REFERENCE TO RELATED APPLICATION

The present application claims priority to, and benefit of, Korean Patent Application No. 10-2024-0018328, filed on Feb. 6, 2024, in the Korean Intellectual Property Office, the entire disclosure of which is incorporated herein by reference.

### BACKGROUND

### 1. Field

Embodiments relate to a display device including an inorganic light-emitting element, a method of manufacturing the display device, and an electronic device including the display device.

### 2. Description of the Related Art

As information technology develops, importance of a display device as a connection medium between users and information is emerging. Accordingly, use of display devices, such as a liquid crystal display device, an organic light-emitting display device, a plasma display device, and a micro LED display device, is increasing.

The micro LED display device may include an inorganic light-emitting element. The inorganic light-emitting element is a semiconductor light-emitting element that converts current into light, and that has high light conversion efficiency. In addition, the inorganic light-emitting element is a semi-permanent and environmentally friendly light-emitting element, and its energy consumption is very low.

### SUMMARY

Embodiments provide a display device with improved quality.

Embodiments provide a method of manufacturing the display device.

Embodiments provide an electronic device including the display device.

A display device according to one or more embodiments includes a first electrode above a substrate, a second electrode above the substrate, and spaced apart from the first electrode in a first direction, an inorganic light-emitting element in a first auxiliary pixel area, above the first electrode, and connected to the first electrode, an organic light-emitting layer above the substrate, in a second auxiliary pixel area spaced apart from the first auxiliary pixel area in the first direction, and covering the second electrode, and a third electrode above the organic light-emitting layer.

The third electrode may be spaced apart from the inorganic light-emitting element in plan view.

The display device may further include a connection electrode above the substrate, in a portion of the second auxiliary pixel area, configured to receive a low power supply voltage, and connected to the third electrode.

The connection electrode may at least partially overlap the third electrode in plan view.

The display device may further include a fourth electrode in a portion of the first auxiliary pixel area, above the substrate, and connected to the inorganic light-emitting element.

The fourth electrode may be spaced apart from the third electrode in plan view.

The display device may further include a pixel-defining layer above the substrate, surrounding the second auxiliary pixel area in plan view, and spaced apart from the third electrode in plan view.

A portion of the third electrode may be above the organic light-emitting layer, and another portion of the third electrode may be above the inorganic light-emitting element.

The third electrode may at least partially overlap the inorganic light-emitting element in plan view.

The third electrode may be continuously over the first auxiliary pixel area and the second auxiliary pixel area.

The inorganic light-emitting element may include a first semiconductor layer, an active layer above the first semiconductor layer, and a second semiconductor layer above the active layer.

The display device may further include an insulating layer covering both sides of the first semiconductor layer, both sides of the active layer, both sides of the second semiconductor layer, and an upper surface of the second semiconductor layer.

The third electrode may be spaced apart from the inorganic light-emitting element with the insulating layer therebetween.

The display device may further include a fourth electrode in a portion of the first auxiliary pixel area, above the substrate, connected to the inorganic light-emitting element, and covered by the insulating layer.

The third electrode may be spaced apart from the fourth electrode with the insulating layer therebetween.

The display device may further include a pixel-defining layer above the substrate, surrounding the second auxiliary pixel area in plan view, and covered by the third electrode.

The organic light-emitting layer may be configured to emit green light or red light.

A method of manufacturing a display device according to one or more embodiments includes forming a first electrode above a substrate, forming a second electrode spaced apart from the first electrode in a first direction above the substrate, bonding the first electrode and an inorganic light-emitting element, forming an organic light-emitting layer covering the second electrode, and forming a third electrode spaced apart from the inorganic light-emitting element in plan view above the organic light-emitting layer.

The bonding the first electrode and the inorganic light-emitting element may be performed before the forming the organic light-emitting layer.

The method may further include forming a contact hole connecting the third electrode and a connection electrode above the substrate, wherein the connection electrode is configured to be applied with a low power supply voltage.

An electronic device according to one or more embodiments includes a first electrode above a substrate, a second electrode above the substrate, and spaced apart from the first electrode in a first direction, an inorganic light-emitting element in a first auxiliary pixel area, above the first electrode, and connected to the first electrode, an organic light-emitting layer above the substrate, in a second auxiliary pixel area spaced apart from the first auxiliary pixel area in the first direction, and covering the second electrode, a third electrode above the organic light-emitting layer, and a memory device configured to store data.

The display device according to one or more embodiments may include both an organic light-emitting layer and an inorganic light-emitting element. The organic light-emitting layer may emit red light or green light. Accordingly, luminous efficiency of red light or green light may be improved.

In addition, transferring the inorganic light-emitting element to the substrate may be performed before forming an organic light-emitting layer on the substrate. Accordingly, damage to the organic light-emitting layer may be reduced or prevented.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments.

FIG. 2 is a cross-sectional view illustrating an example of the display device of FIG. 1 taken along the line I-I′.

FIGS. 3, 4, 5, 6, 7, 8, and 9 are cross-sectional views illustrating a method of manufacturing the display device of FIG. 2.

FIG. 10 is a cross-sectional view illustrating another example of the display device of FIG. 1 taken along the line I-I′.

FIG. 11 is a cross-sectional view illustrating another example of the display device of FIG. 1 taken along the line I-I′.

FIGS. 12, 13, 14, 15, 16, 17, 18, and 19 are cross-sectional views illustrating a method of manufacturing the display device of FIG. 11.

FIG. 20 is a block diagram illustrating an electronic device according to embodiments.

FIG. 21 is a diagram illustrating an example in which the electronic device of FIG. 20 is implemented as a smart phone.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

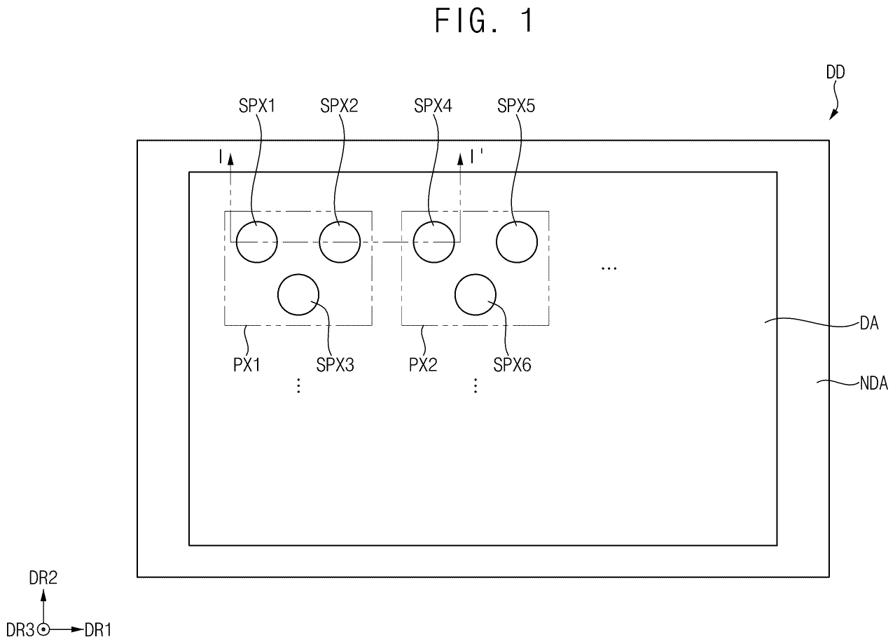

FIG. 1 is a plan view illustrating a display device according to one or more embodiments.

Referring to FIG. 1, a display device DD may include a display area DA and a non-display area NDA. The display area DA may be defined as an area that emits light. In addition, the non-display area NDA may be defined as an area that does not emit light. For example, the non-display area NDA may surround at least a portion of the display area DA (e.g., in plan view).

A plurality of pixel areas may be located in the display area DA. For example, a first pixel area PX1 and a second pixel area PX2 may be located in the display area DA. Each of the plurality of pixel areas may emit light. Accordingly, the display area DA of the display device DD may display an image.

The plurality of pixel areas may be repeatedly arranged in a first direction DR1, and in a second direction DR2 crossing the first direction DR1. For example, the second pixel area PX2 may be spaced apart from the first pixel area PX1 in the first direction DR1.

Each of the plurality of pixel areas may include a plurality of auxiliary pixel areas. For example, the first pixel area PX1 may include a first auxiliary pixel area SPX1, a second auxiliary pixel area SPX2, and a third auxiliary pixel area SPX3. In addition, the second pixel area PX2 may include a fourth auxiliary pixel area SPX4, a fifth auxiliary pixel area SPX5, and a sixth auxiliary pixel area SPX6.

The first auxiliary pixel area SPX1 may emit first light, the second auxiliary pixel area SPX2 may emit second light, and the third auxiliary pixel area SPX3 may emit third light. For example, the first light may be blue light, the second light may be red light, and the third light may be green light. However, this disclosure is not limited thereto, and wavelengths of each of the first light, the second light, and the third light may be changed.

As each of the first auxiliary pixel area SPX1, the second auxiliary pixel area SPX2, and the third auxiliary pixel area SPX3 emits light, the first pixel area PX1 may emit light having a corresponding wavelength. In addition, as each of the fourth auxiliary pixel area SPX4, the fifth auxiliary pixel area SPX5, and the sixth auxiliary pixel area SPX6 emits light, the second pixel area PX2 may emit light having a corresponding wavelength.

A driver may be located in the non-display area NDA. The driver may provide signals or voltages to the plurality of pixel areas. For example, the driver may include a data driver, a gate driver, and/or the like.

In this present specification, the first direction DR1, and the second direction DR2 crossing the first direction DR1, may be defined. In addition, a third direction DR3 that is substantially perpendicular to a plane formed by the first direction DR1 and the second direction DR2 may be defined.

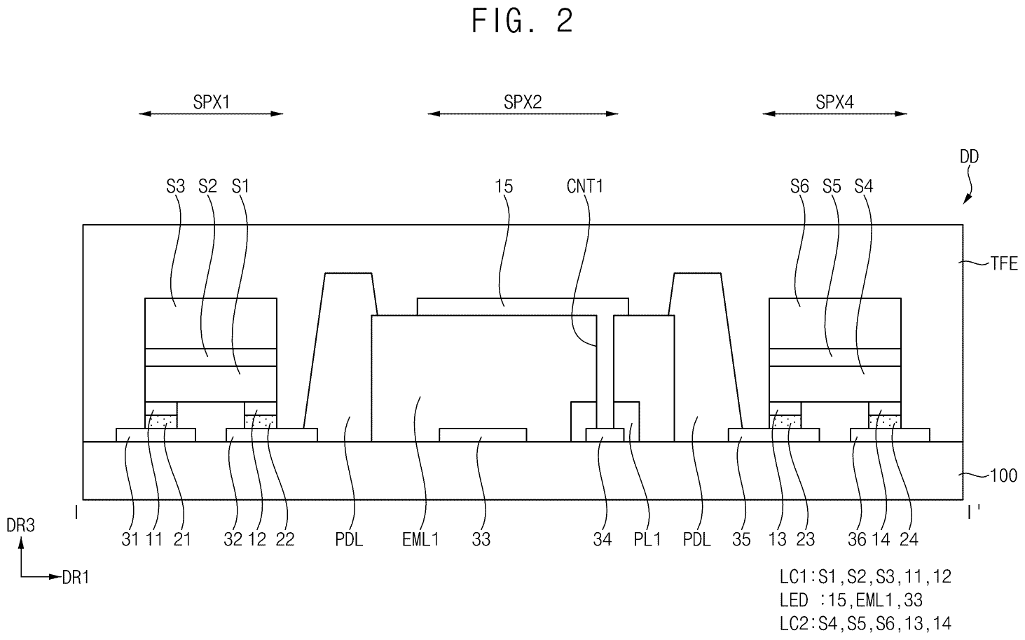

FIG. 2 is a cross-sectional view illustrating an example of the display device of FIG. 1 taken along the line I-I′.

Referring further to FIG. 2, the display device DD may include a substrate 100, a first inorganic light-emitting element LC1, a second inorganic light-emitting element LC2, a light-emitting element LED, a first adhesive member 21, a second adhesive member 22, a third adhesive member 23, a fourth adhesive member 24, a first anode electrode 31, a second anode electrode 33, a third anode electrode 35, a first cathode electrode 32, a second cathode electrode 15, a third cathode electrode 36, a first insulating layer PL1, a connection electrode 34, an organic light-emitting layer EML1, a pixel-defining layer PDL, and an encapsulation layer TFE.

The substrate 100 may include a transparent material or an opaque material. The substrate 100 may be formed of a transparent resin substrate. A transparent resin substrate may include a polyimide substrate. In this case, the polyimide substrate may include a first organic layer, a first barrier layer, a second organic layer, and/or the like.

Alternatively, the substrate 100 may include a quartz substrate (e.g. a synthetic quartz substrate, a fluorine-doped quartz substrate), a calcium fluoride substrate, a soda-lime glass substrate, a non-alkali glass substrate, or the like. These materials may be used alone or in combination with each other.

The substrate 100 may include a circuit element capable of controlling each of the first inorganic light-emitting element LC1, the second inorganic light-emitting element LC2, and the light-emitting element LED. For example, the substrate 100 may include a TFT, a PMOS, an NMOS, a CMOS structure, and/or the like.

The first inorganic light-emitting element LC1 may include a first semiconductor layer S1, an active layer S2, a second semiconductor layer S3, a first lower electrode 11, and a second lower electrode 12. The second inorganic light-emitting element LC2 may include a first semiconductor layer S4, an active layer S5, a second semiconductor layer S6, a third lower electrode 13, and a fourth lower electrode 14. The light-emitting element LED may include the second cathode electrode 15, the organic light-emitting layer EML1, and the second anode electrode 33.

The first anode electrode 31 may be located on the substrate 100 (as used herein, “located on” may mean “above”). The first anode electrode 31 may be located in a portion of the first auxiliary pixel area SPX1. The first anode electrode 31 may operate as an anode of the first inorganic light-emitting element LC1. For example, the first anode electrode 31 may be referred to as a first electrode.

For example, the first anode electrode 31 may include a metal, an alloy, a metal nitride, a conductive metal oxide, a transparent conductive material, or the like. In one or more embodiments, the first anode electrode 31 may include molybdenum (Mo), aluminum (Al), chromium (Cr), titanium (Ti), gold (Au), nickel (Ni), neodymium (Nd), copper (Cu), or the like. These materials may be used alone or in combination with each other. However, this disclosure is not limited thereto, and in one or more other embodiments, the first anode electrode 31 may have a stacked structure including ITO/Ag/ITO.

The first inorganic light-emitting element LC1 may be located in the first auxiliary pixel area SPX1. For example, the first inorganic light-emitting element LC1 may be located on the first anode electrode 31. For example, the first lower electrode 11 may be located on the first anode electrode 31. The first inorganic light-emitting element LC1 may be electrically connected to the first anode electrode 31 through the first lower electrode 11.

For example, the first lower electrode 11 may include an alloy, a metal nitride, a conductive metal oxide, a transparent conductive material, or the like. In one or more embodiments, the first lower electrode 11 may include molybdenum (Mo), aluminum (Al), chromium (Cr), titanium (Ti), gold (Au), nickel (Ni), neodymium (Nd), copper (Cu), or the like. These materials may be used alone or in combination with each other.

In one or more embodiments, the first lower electrode 11 and the first anode electrode 31 may be adhered to each other through the first adhesive member 21. For example, the first adhesive member 21 may include a solder bump, a solder ball, an anisotropic conductive film, an anisotropic conductive paste, and/or the like. However, this disclosure is not limited thereto, and the first adhesive member 21 may be omitted. For example, the first lower electrode 11 and the first anode electrode 31 may be eutectically bonded.

The first cathode electrode 32 may be located on the substrate 100. The first cathode electrode 32 may be located in a portion of the first auxiliary pixel area SPX1. For example, the first cathode electrode 32 may be spaced apart from the first anode electrode 31 in the first direction DR1. The first cathode electrode 32 may operate as a cathode of the first inorganic light-emitting element LC1. For example, the first cathode electrode 32 may be referred to as a fourth electrode.

For example, the first cathode electrode 32 may include an alloy, a metal nitride, a conductive metal oxide, a transparent conductive material, or the like. In one or more embodiments, the first cathode electrode 32 may include molybdenum (Mo), aluminum (Al), chromium (Cr), titanium (Ti), gold (Au), nickel (Ni), neodymium (Nd), copper (Cu), or the like. These materials may be used alone or in combination with each other.

The first inorganic light-emitting element LC1 may be located on the first cathode electrode 32. For example, the second lower electrode 12 may be located on the first cathode electrode 32. The first inorganic light-emitting element LC1 may be electrically connected to the first cathode electrode 32 through the second lower electrode 12. For example, the second lower electrode 12 and the first lower electrode 11 may include substantially the same material.

In one or more embodiments, the second lower electrode 12 and the first cathode electrode 32 may be adhered to each other through the second adhesive member 22. For example, the second adhesive member 22 and the first adhesive member 21 may include substantially the same material. However, this disclosure is not limited thereto, and the second adhesive member 22 may be omitted. For example, the second lower electrode 12 and the first cathode electrode 32 may be eutectically bonded.

The first semiconductor layer S1, the active layer S2, and the second semiconductor layer S3 may be located on the first lower electrode 11 and the second lower electrode 12. For example, the first semiconductor layer S1, the active layer S2, and the second semiconductor layer S3 may be sequentially stacked on the first lower electrode 11 and the second lower electrode 12 along the third direction DR3.

In one or more embodiments, the first semiconductor layer S1 may include a p-type semiconductor layer. For example, the first semiconductor layer S1 may include a semiconductor material, such as GaN, InAlGaN, AlGaN, InGaN, AlN, InN, or the like, and may include a p-type semiconductor layer doped with a first conductive dopant (e.g., a p-type dopant), such as Zn, Fe, Mg, Be, Cd, Ag, C, Hg, Li, Ca, or the like. For example, the first semiconductor layer S1 may include a GaN semiconductor material doped with the first conductive dopant.

The active layer S2 may be located on the first semiconductor layer S1. For example, the active layer S2 may include a single-well structure, a multi-well structure, a single-quantum well structure, a multi-quantum well structure, a quantum dot structure, or a quantum wire structure. For example, the active layer S2 may include a multi-quantum well structure. In this case, the active layer S2 may include a structure in which well layers and barrier layers are alternately stacked. The well layer may include InGaN, and the barrier layer may include GaN or AlGaN, but this disclosure is not limited thereto.

The second semiconductor layer S3 may be located on the active layer S2. In one or more embodiments, the second semiconductor layer S3 may include an n-type semiconductor layer. For example, the second semiconductor layer S3 may include a semiconductor material, such as GaN, InAlGaN, AlGaN, InGaN, AlN, InN, or the like, and may include an n-type semiconductor layer doped with a second conductive dopant (e.g., an n-type dopant), such as Si, Sn, Te, Se, S, O, Ti, Ge, or the like. For example, the second semiconductor layer S3 may include a GaN semiconductor material doped with the second conductive dopant. However, this disclosure is not limited thereto, and in one or more other embodiments, the first semiconductor layer S1 may include an n-type semiconductor layer, and the second semiconductor layer S3 may include a p-type semiconductor layer.

In one or more embodiments, the first inorganic light-emitting element LC1 may be a flip chip type including a first lower electrode 11 facing the first anode electrode 31 and a second lower electrode 12 facing the first cathode electrode 32. However, this disclosure is not limited thereto, and in one or more other embodiments, the first inorganic light-emitting element LC1 may be a lateral chip type or a vertical chip type.

The second anode electrode 33 may be located on the substrate 100. The second anode electrode 33 may be located in a portion of the second auxiliary pixel area SPX2. For example, the second anode electrode 33 may be spaced apart from the first anode electrode 31 in the first direction DR1. In addition, the second anode electrode 33 may be spaced apart from the first cathode electrode 32 in the first direction DR1. For example, the second anode electrode 33 may be referred to as a second electrode.

The second anode electrode 33 may operate as an anode electrode of the light-emitting element LED. For example, the second anode electrode 33 may include a metal, an alloy, a metal nitride, a conductive metal oxide, a transparent conductive material, or the like. These materials may be used alone or in combination with each other. In one or more embodiments, the second anode electrode 33 may have a stacked structure including ITO/Ag/ITO.

The connection electrode 34 may be located on the substrate 100. The connection electrode 34 may be located in a portion of the second auxiliary pixel area SPX2. For example, the connection electrode 34 may be spaced apart from the second anode electrode 33 in the first direction DR1.

In one or more embodiments, a first width of the connection electrode 34 in the first direction DR1 may be less than a second width of the second anode electrode 33 in the first direction DR1. In one or more other embodiments, the first width of the connection electrode 34 and the second width of the second anode electrode 33 may be substantially the same. In one or more other embodiments, the first width of the connection electrode 34 may be greater than the second width of the second anode electrode 33.

A power supply voltage may be applied to the connection electrode 34. For example, a low power supply voltage, such as ELVSS, may be applied to the connection electrode 34 from the substrate 100. The power supply voltage may be applied to the second cathode electrode 15 through the connection electrode 34. The connection electrode 34 may at least partially overlap the second cathode electrode 15 in a plan view. For example, the connection electrode 34 may include a metal, an alloy, a metal nitride, a conductive metal oxide, a transparent conductive material, or the like. These materials may be used alone or in combination with each other.

The first insulating layer PL1 may cover the connection electrode 34. Accordingly, the first insulating layer PL1 may reduce or prevent the likelihood of the connection electrode 34 directly contacting the organic light-emitting layer EML1.

For example, the first insulating layer PL1 may include silicon oxide (SiOx), silicon nitride (SiNₓ), silicon oxynitride (SiOₓN_{y}), silicon oxynitride (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like. These materials may be used alone or in combination with each other.

The organic light-emitting layer EML1 may be located on the substrate 100. The organic light-emitting layer EML1 may be located in the second auxiliary pixel area SPX2. That is, the organic light-emitting layer EML1 may be spaced apart from the first inorganic light-emitting element LC1 in the first direction DR1. The organic light-emitting layer EML1 may cover the second anode electrode 33 and the first insulating layer PL1. The organic light-emitting layer EML1 may include an organic material that emits light of a color (e.g., a predetermined color).

The second cathode electrode 15 may be located on the organic light-emitting layer EML1. The second cathode electrode 15 may be located in the second auxiliary pixel area SPX2. In one or more embodiments, the second cathode electrode 15 may be located only in the second auxiliary pixel area SPX2. That is, the second cathode electrode 15 may not be located in the first auxiliary pixel area SPX1 and the fourth auxiliary pixel area SPX4. For example, the second cathode electrode 15 may be referred to as a third electrode.

That is, the second cathode electrode 15 may be spaced apart from the first inorganic light-emitting element LC1 in the plan view. The second cathode electrode 15 may be spaced apart from the first anode electrode 31 and the first cathode electrode 32 in the plan view.

In addition, the second cathode electrode 15 may be spaced apart from the second inorganic light-emitting element LC2 in the plan view. The second cathode electrode 15 may be spaced apart from the third anode electrode 35 and the third cathode electrode 36 in the plan view.

In one or more embodiments, the second cathode electrode 15 may be spaced apart from the pixel-defining layer PDL to be described later. However, this disclosure is not limited thereto, and in one or more other embodiments, the second cathode electrode 15 may cover at least a portion of the pixel-defining layer PDL.

The second cathode electrode 15 may be connected to the connection electrode 34. For example, the second cathode electrode 15 may be connected to the connection electrode 34 through a contact hole CNT1. The contact hole CNT1 may be defined through the organic light-emitting layer EML1 and the first insulating layer PL1. For example, the second cathode electrode 15 may include a metal, an alloy, a metal nitride, a conductive metal oxide, a transparent conductive material, or the like. These materials may be used alone or in combination with each other.

The pixel-defining layer PDL may be located on the substrate 100. For example, the pixel-defining layer PDL may have a shape surrounding the second auxiliary pixel area SPX2 in the plan view. The pixel-defining layer PDL may have, or may define, an opening overlapping the second auxiliary pixel area SPX2 in the plan view. At least a portion of each of the second anode electrode 33, the organic light-emitting layer EML1, and the second cathode electrode 15 may be located in the opening of the pixel-defining layer PDL.

As shown in FIG. 2, a first portion of the pixel-defining layer PDL may be located between the first auxiliary pixel area SPX1 and the second auxiliary pixel area SPX2. That is, the first portion of the pixel-defining layer PDL may be located between the first inorganic light-emitting element LC1 and the organic light-emitting layer EML1. In addition, a second portion of the pixel-defining layer PDL may be located between the second auxiliary pixel area SPX2 and the fourth auxiliary pixel area SPX4. That is, the second portion of the pixel-defining layer PDL may be located between the second inorganic light-emitting element LC2 and the organic light-emitting layer EML1.

For example, the pixel-defining layer PDL may include an inorganic material or an organic material. In one or more embodiments, the pixel-defining layer PDL may include an organic material, such as an epoxy resin, a siloxane resin, or the like. These materials may be used alone or in combination with each other. In one or more other embodiments, the pixel-defining layer PDL may further include a light-blocking material containing a black pigment, a black dye, or the like.

The third anode electrode 35 may be located on the substrate 100. The third anode electrode 35 may be located in a portion of the fourth auxiliary pixel area SPX4. For example, the third anode electrode 35 may be spaced apart from the connection electrode 34 in the first direction DR1. The third anode electrode 35 may operate as an anode of the second inorganic light-emitting element LC2. For example, the third anode electrode 35 and the first anode electrode 31 may include substantially the same material.

The second inorganic light-emitting element LC2 may be located in the fourth auxiliary pixel area SPX4. For example, the second inorganic light-emitting element LC2 may be located on the third anode electrode 35. For example, the third lower electrode 13 may be located on the third anode electrode 35. The second inorganic light-emitting element LC2 may be electrically connected to the third anode electrode 35 through the third lower electrode 13. For example, the third lower electrode 13 and the first lower electrode 11 may include substantially the same material.

In one or more embodiments, the third lower electrode 13 and the third anode electrode 35 may be adhered to each other through the third adhesive member 23. For example, the third adhesive member 23 and the first adhesive member 21 may include substantially the same material. However, this disclosure is not limited thereto, and the third adhesive member 23 may be omitted. For example, the third lower electrode 13 and the third cathode electrode 35 may be eutectically bonded.

The third cathode electrode 36 may be located on the substrate 100. The third cathode electrode 36 may be located in a portion of the fourth auxiliary pixel area SPX4. For example, the third cathode electrode 36 may be spaced apart from the third anode electrode 35 in the first direction DR1. The third cathode electrode 36 may operate as a cathode of the second inorganic light-emitting element LC2. For example, the third cathode electrode 36 and the first cathode electrode 32 may include substantially the same material.

The second inorganic light-emitting element LC2 may be located on the third cathode electrode 36. For example, the fourth lower electrode 14 may be located on the third cathode electrode 36. The second inorganic light-emitting element LC2 may be electrically connected to the third cathode electrode 36 through the fourth lower electrode 14. For example, the fourth lower electrode 14 and the first lower electrode 11 may include substantially the same material.

In one or more embodiments, the fourth lower electrode 14 and the third cathode electrode 36 may be adhered to each other through the fourth adhesive member 24. For example, the fourth adhesive member 24 and the first adhesive member 21 may include substantially the same material. However, this disclosure is not limited thereto, and the fourth adhesive member 24 may be omitted. For example, the fourth lower electrode 14 and the third cathode electrode 36 may be eutectically bonded.

The first semiconductor layer S4, the active layer S5, and the second semiconductor layer S6 may be located on the third lower electrode 13 and the fourth lower electrode 14. For example, the first semiconductor layer S4, the active layer S5, and the second semiconductor layer S6 may be sequentially stacked on the third lower electrode 13 and the fourth lower electrode 14 along the third direction DR3.

In one or more embodiments, the first semiconductor layer S4 may include a p-type semiconductor layer. For example, the first semiconductor layer S4 may include a semiconductor material, such as GaN, InAlGaN, AlGaN, InGaN, AlN, InN, or the like, and may include a p-type semiconductor layer doped with a first conductive dopant (e.g., a p-type dopant), such as Zn, Fe, Mg, Be, Cd, Ag, C, Hg, Li, Ca, or the like. For example, the first semiconductor layer S4 may include a GaN semiconductor material doped with the first conductive dopant.

The active layer S5 may be located on the first semiconductor layer S4. For example, the active layer S5 may include a single-well structure, a multi-well structure, a single-quantum well structure, a multi-quantum well structure, a quantum dot structure, or a quantum wire structure. For example, the active layer S5 may include a multi-quantum well structure. In this case, the active layer S5 may include a structure in which well layers and barrier layers are alternately stacked. The well layer may include InGaN, and the barrier layer may include GaN or AlGaN, but this disclosure is not limited thereto.

The second semiconductor layer S6 may be located on the active layer S5. In one or more embodiments, the second semiconductor layer S6 may include an n-type semiconductor layer. For example, the second semiconductor layer S6 may include a semiconductor material, such as GaN, InAlGaN, AlGaN, InGaN, AlN, InN, or the like, and may include an n-type semiconductor layer doped with a second conductive dopant (e.g., an n-type dopant), such as Si, Sn, Te, Se, S, O, Ti, Ge, or the like. For example, the second semiconductor layer S6 may include a GaN semiconductor material doped with the second conductive dopant. However, this disclosure is not limited thereto, and in one or more other embodiments, the first semiconductor layer S4 may include an n-type semiconductor layer, and the second semiconductor layer S6 may include a p-type semiconductor layer.

In one or more embodiments, the second inorganic light-emitting element LC2 may be a flip chip type including the third lower electrode 13 facing the third anode electrode 35 and the fourth lower electrode 14 facing the third cathode electrode 36. However, this disclosure is not limited thereto, and in one or more other embodiments, the second inorganic light-emitting element LC2 may be a lateral chip type or a vertical chip type.

The encapsulation layer TFE may be located on the substrate 100. The encapsulation layer TFE may cover the first inorganic light-emitting element LC1, the second inorganic light-emitting element LC2, and the light-emitting element LED. The encapsulation layer TFE may reduce or prevent impurities, moisture, and/or the like from penetrating into the first inorganic light-emitting element LC1, the second inorganic light-emitting element LC2, and the light-emitting element LED from an outside. The encapsulation layer TFE may include at least one inorganic layer and at least one organic layer.

For example, the inorganic layer may include silicon oxide, silicon nitride, silicon oxynitride, or the like. These materials may be used alone or in combination with each other. The organic layer may include a cured polymer material, such as polyacrylate.

Internal quantum efficiency (IQE) of an inorganic light-emitting element (e.g., the first inorganic light-emitting element LC1 or the second inorganic light-emitting element LC2) may have a theoretical limit value due to a decrease in wave function overlap between electrons and holes in an active layer (e.g., the active layer S2 or the active layer S5). Light-emitting efficiency of the inorganic light-emitting element may vary according to the internal quantum efficiency.

For example, internal quantum efficiency of a red inorganic light-emitting element may be lower than internal quantum efficiency of a blue inorganic light-emitting element. That is, a light-emitting efficiency of the red inorganic light-emitting element may be lower than a light-emitting efficiency of the blue inorganic light-emitting element.

In addition, the internal quantum efficiency of the red inorganic light-emitting element may be lower than internal quantum efficiency of a green inorganic light-emitting element. That is, the light-emitting efficiency of the red inorganic light-emitting element may be lower than light-emitting efficiency of the green inorganic light-emitting element.

In addition, the internal quantum efficiency of the green inorganic light-emitting element may be lower than the internal quantum efficiency of the blue inorganic light-emitting element. That is, the light-emitting efficiency of the green inorganic light-emitting element may be lower than the light-emitting efficiency of the blue inorganic light-emitting element.

Here, the red inorganic light-emitting element may mean an inorganic light-emitting element capable of emitting red light, the green inorganic light-emitting element may mean an inorganic light-emitting element capable of emitting green light, and the blue inorganic light-emitting element may mean an inorganic light-emitting element capable of emitting blue light.

In one or more embodiments, the light-emitting element LED may emit red light. In detail, the organic light-emitting layer EML1 may emit red light. That is, with respect to red light, the light-emitting element LED including the organic light-emitting layer EML1 may be used instead of the inorganic light-emitting element, so that the light-emitting efficiency of the red light may be improved.

In this case, blue light may be emitted from the first auxiliary pixel area SPX1, and green light may be emitted from the third auxiliary pixel area SPX3. That is, in one or more embodiments, the first inorganic light-emitting element LC1 may emit blue light, and a third inorganic light-emitting element may emit green light. The third inorganic light-emitting element may be located in the third auxiliary pixel area SPX3.

Alternatively, green light may be emitted from the first auxiliary pixel area SPX1, and blue light may be emitted from the third auxiliary pixel area SPX3. That is, the first inorganic light-emitting element LC1 may emit green light, and the third inorganic light-emitting element may emit blue light.

However, this disclosure is not limited thereto, and in one or more other embodiments, the light-emitting element LED may emit green light. That is, the organic light-emitting layer EML1 may emit green light. In this case, a second light-emitting element having substantially the same structure as the light-emitting element LED may be located in the third auxiliary pixel area SPX3. The second light-emitting element may emit red light. That is, green light may be emitted from the second auxiliary pixel area SPX2, and red light may be emitted from the third auxiliary pixel area SPX3.

That is, with respect to green light and red light, the light-emitting efficiency of each of the green light and red light may be improved by using the light-emitting element LED and the second light-emitting element instead of the inorganic light-emitting element.

In this case, blue light may be emitted from the first auxiliary pixel area SPX1. That is, the first inorganic light-emitting element LC1 may emit blue light. The blue light may have a shorter wavelength and higher energy than the red light and the green light. Thus, the blue light may cause an organic material to collapse, and stability of the organic material may be deteriorated. Thus, it may be suitable for the inorganic light-emitting element to emit blue light.

Alternatively, the light-emitting element LED may emit red light, and the second light-emitting element may emit green light. That is, blue light may be emitted from the first auxiliary pixel area SPX1, red light may be emitted from the second auxiliary pixel area SPX2, and green light may be emitted from the third auxiliary pixel area SPX3.

Although the first pixel area PX1 including the first auxiliary pixel area SPX1, the second auxiliary pixel area SPX2, and the third auxiliary pixel area SPX3 has been described with reference to FIGS. 1 and 2, this disclosure is not limited thereto, and the second pixel area PX2 and the first pixel area PX1 may also include substantially the same structure.

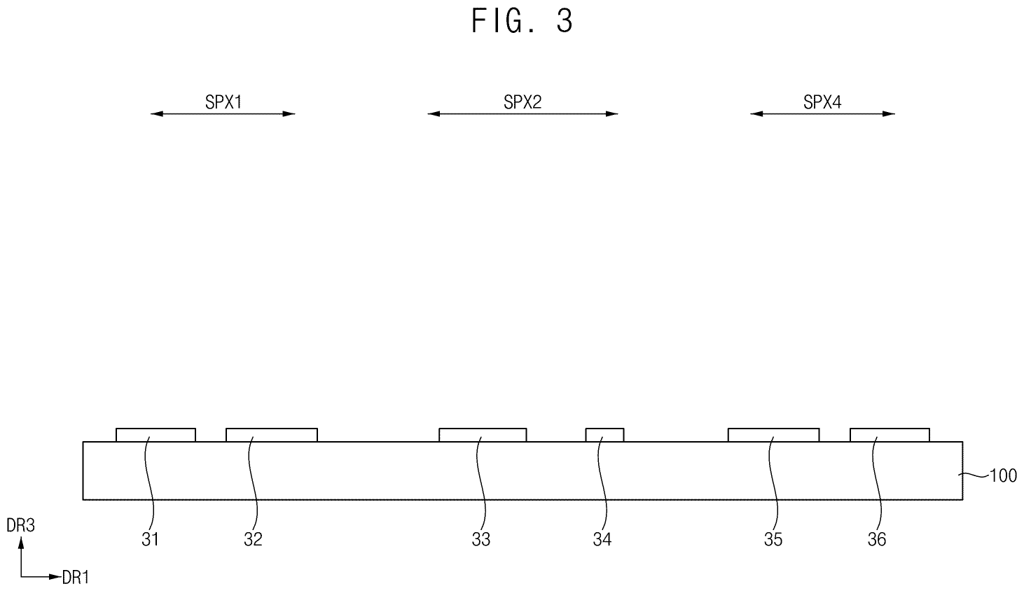

FIGS. 3, 4, 5, 6, 7, 8, and 9 are cross-sectional views illustrating a method of manufacturing the display device of FIG. 2.

Referring to FIG. 3, the first anode electrode 31, the first cathode electrode 32, the second anode electrode 33, the connection electrode 34, the third anode electrode 35, and the third cathode electrode 36 may be formed on the substrate 100 (as used herein, “formed on” may mean “formed above”).

The first anode electrode 31 may be formed in a portion of the first auxiliary pixel area SPX1. For example, the first anode electrode 31 may include a metal, an alloy, a metal nitride, a conductive metal oxide, a transparent conductive material, or the like. These materials may be used alone or in combination with each other.

The first cathode electrode 32 may be formed in a portion of the first auxiliary pixel area SPX1. For example, the first cathode electrode 32 may be spaced apart from the first anode electrode 31 in the first direction DR1. For example, the first cathode electrode 32 may include a metal, an alloy, a metal nitride, a conductive metal oxide, a transparent conductive material, or the like. These materials may be used alone or in combination with each other.

The second anode electrode 33 may be formed in a portion of the second auxiliary pixel area SPX2. For example, the second anode electrode 33 may be spaced apart from the first anode electrode 31 in the first direction DR1. In addition, the second anode electrode 33 may be spaced apart from the first cathode electrode 32 in the first direction DR1. For example, the second anode electrode 33 may include a metal, an alloy, a metal nitride, a conductive metal oxide, a transparent conductive material, or the like. These materials may be used alone or in combination with each other.

The connection electrode 34 may be formed in a portion of the second auxiliary pixel area SPX2. For example, the connection electrode 34 may be spaced apart from the second anode electrode 33 in the first direction DR1. For example, the connection electrode 34 may include a metal, an alloy, a metal nitride, a conductive metal oxide, a transparent conductive material, or the like. These materials may be used alone or in combination with each other.

The third anode electrode 35 may be formed in a portion of the fourth auxiliary pixel area SPX4. For example, the third anode electrode 35 may be spaced apart from the connection electrode 34 in the first direction DR1. For example, the third anode electrode 35 and the first anode electrode 31 may include substantially the same material.

The third cathode electrode 36 may be formed in a portion of the fourth auxiliary pixel area SPX4. For example, the third cathode electrode 36 may be spaced apart from the third anode electrode 35 in the first direction DR1. For example, the third cathode electrode 36 and the first cathode electrode 32 may include substantially the same material.

In one or more embodiments, the first anode electrode 31, the first cathode electrode 32, the second anode electrode 33, the connection electrode 34, the third anode electrode 35, and the third cathode electrode 36 may be formed concurrently or substantially simultaneously. For example, a conductive layer is formed on the substrate 100, and the conductive layer may be etched by an etching process or the like to concurrently or substantially simultaneously form the first anode electrode 31, the first cathode electrode 32, the second anode electrode 33, the connection electrode 34, the third anode electrode 35, and the third cathode electrode 36.

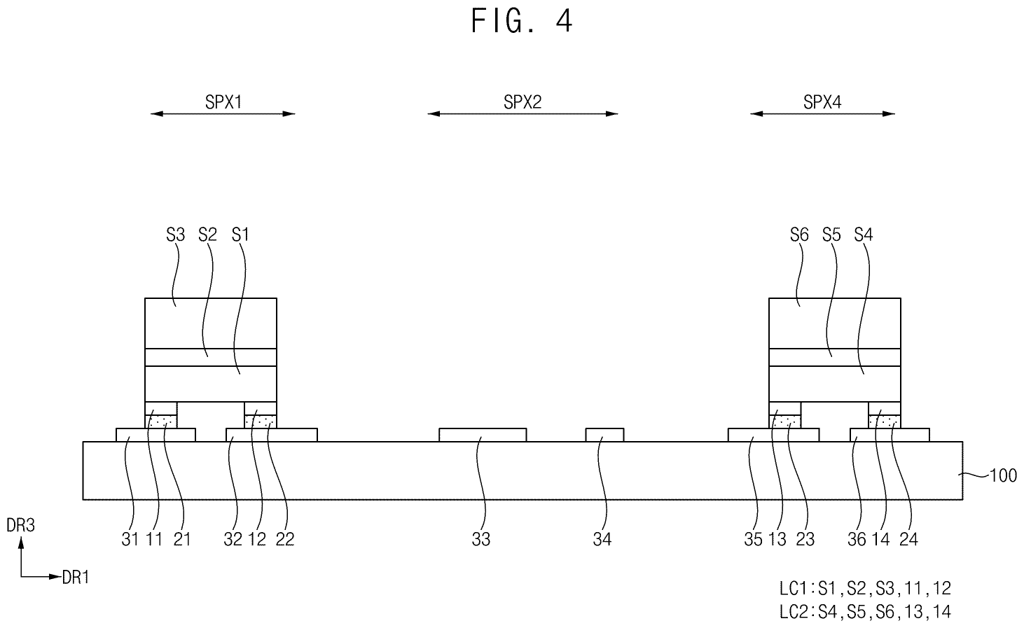

Referring to FIG. 4, the first inorganic light-emitting element LC1 may be attached to the first anode electrode 31 and the first cathode electrode 32. For example, the first lower electrode 11 may be attached to the first anode electrode 31 through the first adhesive member 21, and the second lower electrode 12 may be attached to the first cathode electrode 32 through the second adhesive member 22. That is, the first inorganic light-emitting element LC1 may be transferred to the substrate 100.

The first inorganic light-emitting element LC1 may include the first semiconductor layer S1, the active layer S2, the second semiconductor layer S3, the first lower electrode 11, and the second lower electrode 12. The first semiconductor layer S1, the active layer S2, and the second semiconductor layer S3 may be formed on an epitaxial substrate by an epitaxial growth method. For example, the epitaxial substrate may include a silicon substrate, a sapphire substrate, and/or the like. After the first semiconductor layer S1, the active layer S2, and the second semiconductor layer S3 are formed, the epitaxial substrate may be removed by laser lift-off (LLO), and/or the like.

In one or more embodiments, the first semiconductor layer S1, the active layer S2, and the second semiconductor layer S3 may be formed by metal organic chemical vapor deposition (MOCVD). However, this disclosure is not limited thereto, and in one or more other embodiments, the first semiconductor layer S1, the active layer S2, and the second semiconductor layer S3 may be formed by various processes, such as physical vapor deposition (PVD), electron beam deposition, chemical vapor deposition (CVD), plasma laser deposition (PLD), dual-type thermal evaporation, and/or the like.

Each of the first lower electrode 11 and the second lower electrode 12 may include a metal, an alloy, a metal nitride, a conductive metal oxide, a transparent conductive material, or the like. These materials may be used alone or in combination with each other. In addition, each of the first adhesive member 21 and the second adhesive member 22 may include a solder bump, a solder ball, an anisotropic conductive film, an anisotropic conductive paste, and/or the like.

The second inorganic light-emitting element LC2 may be attached to the third anode electrode 35 and the third cathode electrode 36. For example, the third lower electrode 13 may be attached to the third anode electrode 35 through the third adhesive member 23, and the fourth lower electrode 14 may be attached to the third cathode electrode 36 through the fourth adhesive member 24. That is, the second inorganic light-emitting element LC2 may be transferred to the substrate 100.

The second inorganic light-emitting element LC2 may include the first semiconductor layer S4, the active layer S5, the second semiconductor layer S6, the third lower electrode 13, and the fourth lower electrode 14. The first semiconductor layer S4, the active layer S5, and the second semiconductor layer S6 may be formed on an epitaxial substrate by an epitaxial growth method. For example, the epitaxial substrate may include a silicon substrate, a sapphire substrate, and/or the like. After the first semiconductor layer S4, the active layer S5, and the second semiconductor layer S6 are formed, the epitaxial substrate may be removed by laser lift-off (LLO), and/or the like.

In one or more embodiments, the first semiconductor layer S4, the active layer S5, and the second semiconductor layer S6 may be formed by metal organic chemical vapor deposition (MOCVD). However, this disclosure is not limited thereto, and in one or more other embodiments, the first semiconductor layer S4, the active layer S5, and the second semiconductor layer S6 may be formed by various processes, such as physical vapor deposition (PVD), electron beam deposition, chemical vapor deposition (CVD), plasma laser deposition (PLD), dual-type thermal evaporation, and/or the like.

Each of the third lower electrode 13 and the fourth lower electrode 14 may include a metal, an alloy, a metal nitride, a conductive metal oxide, a transparent conductive material, or the like. These materials may be used alone or in combination with each other. In addition, each of the third adhesive member 23 and the fourth adhesive member 24 may include a solder bump, a solder ball, an anisotropic conductive film, an anisotropic conductive paste, and/or the like.

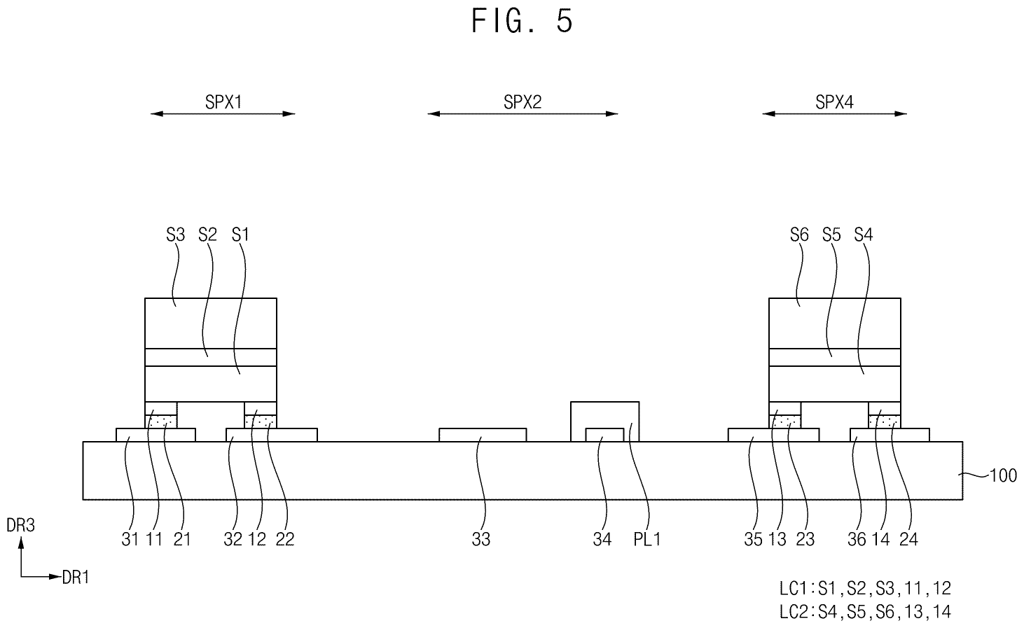

Referring to FIG. 5, the first insulating layer PL1 may be formed on the substrate 100. The first insulating layer PL1 may cover the connection electrode 34. For example, a preliminary insulating layer may be formed on the substrate 100, and a portion of the preliminary insulating layer may be etched by an etching process or the like to form the first insulating layer PL1.

For example, the first insulating layer PL1 may include silicon oxide (SiOx), silicon nitride (SiNₓ), silicon oxynitride (SiOₓN_{y}), silicon oxynitride (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like. These materials may be used alone or in combination with each other.

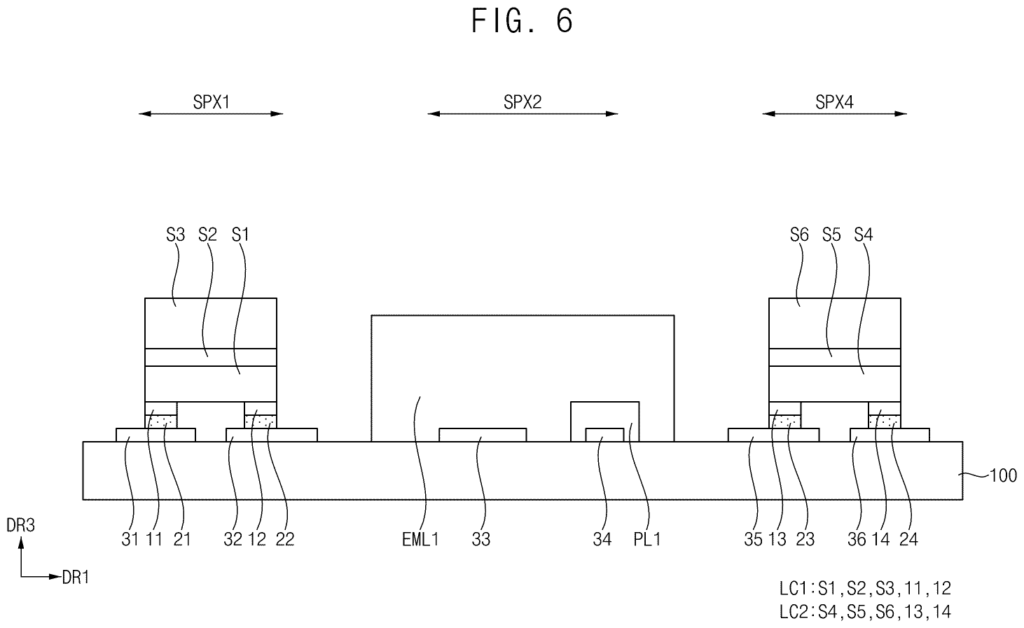

Referring to FIG. 6, the organic light-emitting layer EML1 may be formed on a substrate 100. The organic light-emitting layer EML1 may be formed in the second auxiliary pixel area SPX2. That is, the organic light-emitting layer EML1 may be spaced apart from the first inorganic light-emitting element LC1 in the first direction DR1. The organic light-emitting layer EML1 may cover the second anode electrode 33 and the first insulating layer PL1. The organic light-emitting layer EML1 may include an organic material for emitting light of a color (e.g., a predetermined color). For example, the organic light-emitting layer EML1 may be formed only in the second auxiliary pixel area SPX2 by an evaporation process using a deposition mask. The deposition mask may be a fine metal mask (FMM).

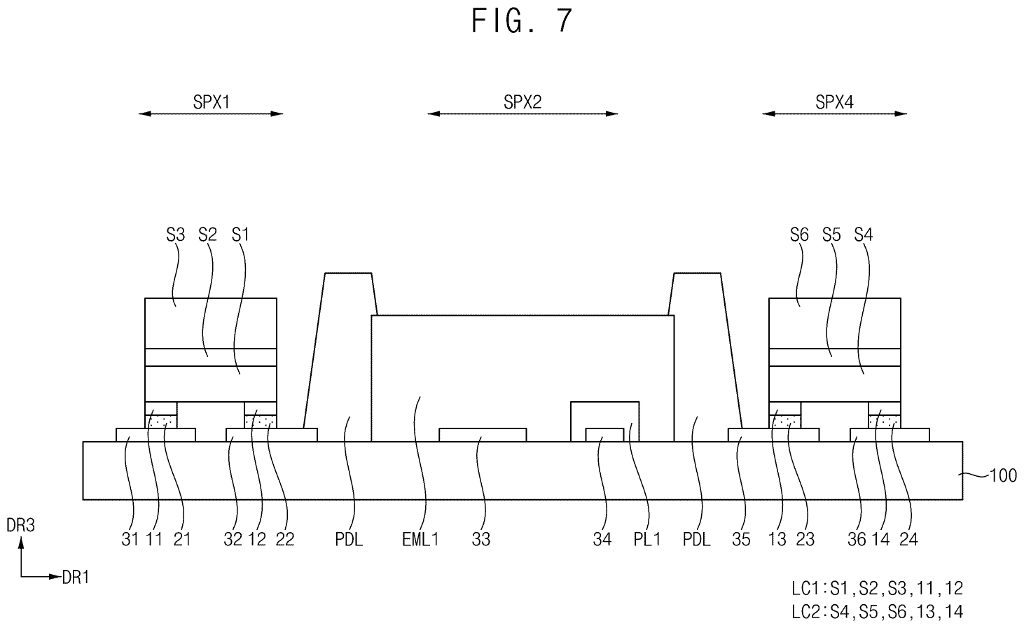

Referring to FIG. 7, the pixel-defining layer PDL may be formed on a substrate 100. For example, the pixel-defining layer PDL may surround the second auxiliary pixel area SPX2 in the plan view. That is, the pixel-defining layer PDL may cover a portion of an upper surface and a side surface of the organic light-emitting layer EML1.

In detail, a first portion of the pixel-defining layer PDL may be formed between the first auxiliary pixel area SPX1 and the second auxiliary pixel area SPX2. That is, the first portion of the pixel-defining layer PDL may be formed between the first inorganic light-emitting element LC1 and the organic light-emitting layer EML1. In addition, a second portion of the pixel-defining layer PDL may be formed between the second auxiliary pixel area SPX2 and the fourth auxiliary pixel area SPX4. That is, the second portion of the pixel-defining layer PDL may be formed between the second inorganic light-emitting element LC2 and the organic light-emitting layer EML1.

For example, the pixel-defining layer PDL may include an inorganic material or an organic material. In one or more embodiments, the pixel-defining layer PDL may include an organic material, such as an epoxy resin, a siloxane resin, or the like. These materials may be used alone or in combination with each other. In one or more other embodiments, the pixel-defining layer PDL may further include a light-blocking material containing a black pigment, a black dye, or the like.

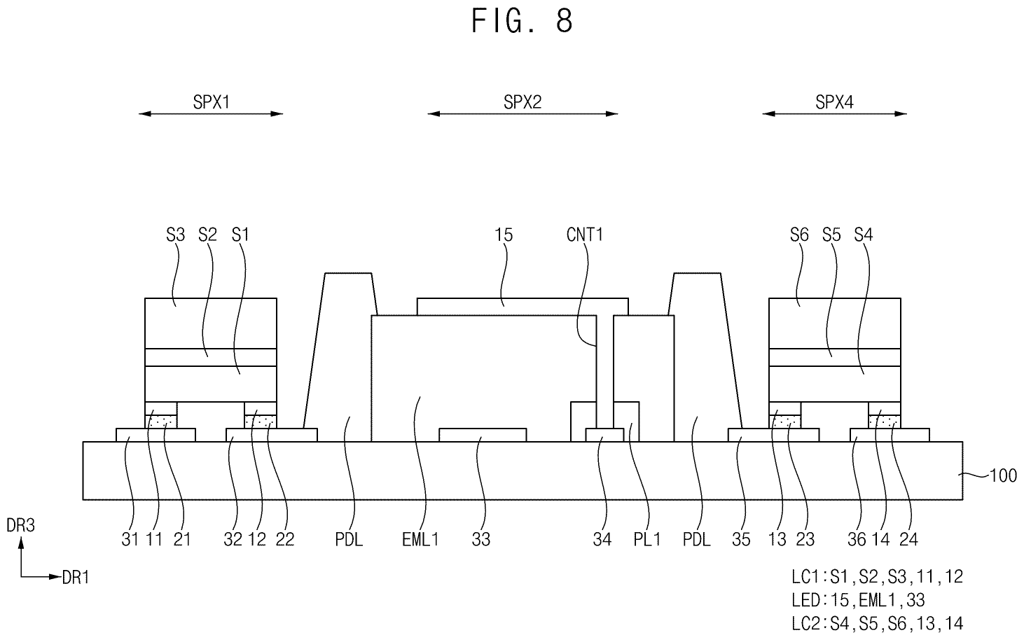

Referring to FIG. 8, the second cathode electrode 15 may be formed on the organic light-emitting layer EML1. The second cathode electrode 15 may be formed in the second auxiliary pixel area SPX2. In one or more embodiments, the second cathode electrode 15 may be formed only in the second auxiliary pixel area SPX2. That is, the second cathode electrode 15 might not be formed in the first auxiliary pixel area SPX1 or in the fourth auxiliary pixel area SPX4. That is, the second cathode electrode 15 may be spaced apart from the first inorganic light-emitting element LC1 in the plan view. In addition, the second cathode electrode 15 may be spaced apart from the second inorganic light-emitting element LC2 in the plan view. In addition, the second cathode electrode 15 may be spaced apart from the pixel-defining layer PDL in the plan view. For example, a preliminary cathode electrode may be formed on the organic light-emitting layer EML1, the pixel-defining layer PDL, the first inorganic light-emitting element LC1, and the second inorganic light-emitting element LC2. A portion of the preliminary cathode electrode may be etched by an etching process or the like to form the second cathode electrode 15.

For example, the second cathode electrode 15 may include a metal, an alloy, a metal nitride, a conductive metal oxide, a transparent conductive material, or the like. These materials may be used alone or in combination with each other.

The contact hole CNT1 may be defined through the organic light-emitting layer EML1 and the first insulating layer PL1. The second cathode electrode 15 may be electrically connected to the connection electrode 34 through the contact hole CNT1.

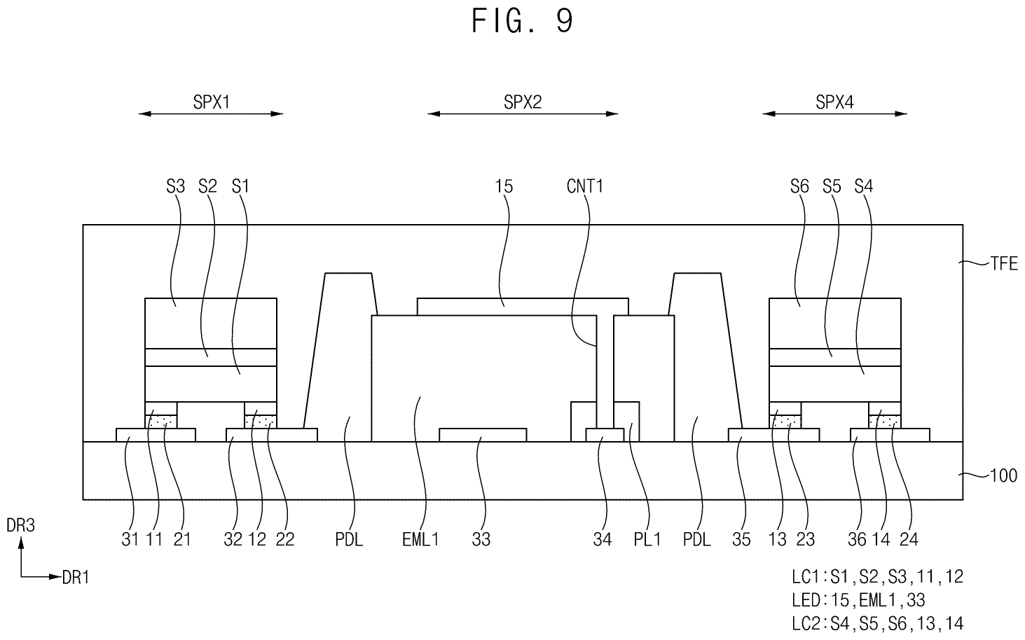

Referring to FIG. 9, The encapsulation layer TFE may be formed on a substrate 100. The encapsulation layer TFE may cover the first inorganic light-emitting element LC1, the second inorganic light-emitting element LC2, and the light-emitting element LED. The encapsulation layer TFE may include at least one inorganic layer and at least one organic layer.

For example, the inorganic layer may include silicon oxide, silicon nitride, silicon oxynitride, or the like. These may be used alone or in combination with each other. The organic layer may include a cured polymer material, such as polyacrylate.

If the organic light-emitting layer EML1 including the organic material is formed on the substrate 100 after each of the first inorganic light-emitting element LC1 and the second inorganic light-emitting element LC2 is transferred to the substrate 100, damage to the organic light-emitting layer EML1 may be caused.

In one or more embodiments, the transferring each of the first inorganic light-emitting LC1 and the second inorganic light-emitting element LC2 to the substrate 100 may be performed before the forming the organic light-emitting layer EML1 on the substrate 100.

That is, the attaching the first inorganic light-emitting element LC1 to the first anode electrode 31 and the first cathode electrode 32 may be performed before the forming the organic light-emitting layer EML1 on the substrate 100. In addition, the attaching the second inorganic light-emitting element LC2 to the third anode electrode 35 and the third cathode electrode 36 may be performed before the forming the organic light-emitting layer EML1 on the substrate 100. Accordingly, damage to the organic light-emitting layer EML1 may be reduced or prevented.

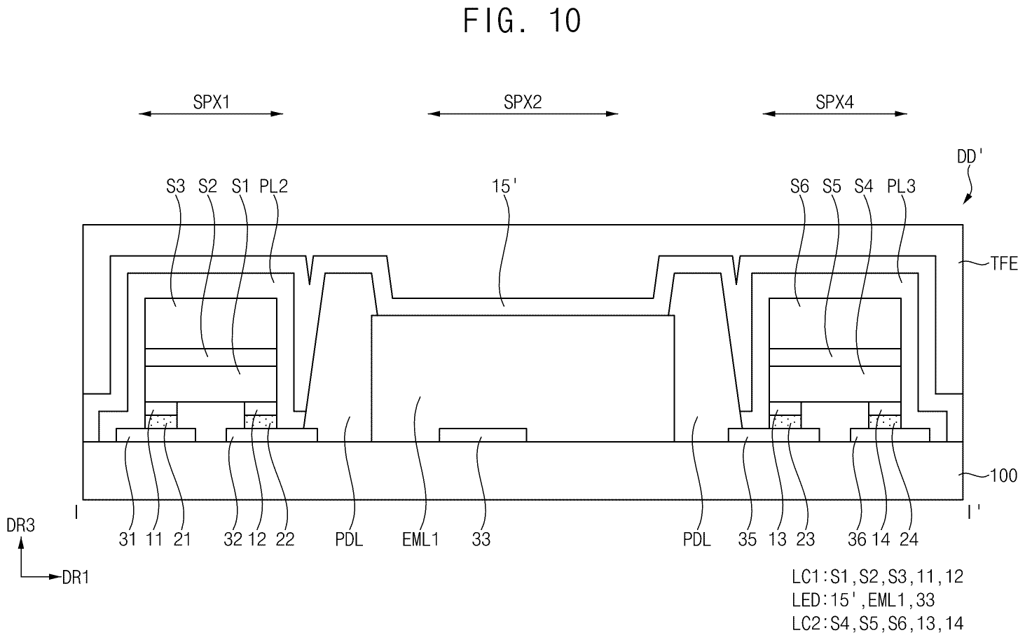

FIG. 10 is a cross-sectional view illustrating another example of the display device of FIG. 1 taken along the line I-I′.

In describing the display device DD′ of FIG. 10, the same reference numerals are assigned to substantially the same elements as the display device DD of FIG. 2, and a detailed description thereof may be omitted.

Referring to FIG. 10, in one or more embodiments, the second insulating layer PL2 may cover the first inorganic light-emitting element LC1. For example, the second insulating layer PL2 may cover side surface of each of the first semiconductor layer S1, the active layer S2, and the second semiconductor layer S3. In addition, the second insulating layer PL2 may cover an upper surface of the second semiconductor layer S3. In addition, the second insulating layer PL2 may extend to cover side surface of each of the first lower electrode 11 and the second lower electrode 12.

In one or more embodiments, the second insulating layer PL2 may extend to cover side surface of each of the first adhesive member 21 and the second adhesive member 22. In one or more embodiments, the second insulating layer PL2 may extend to cover each of the first anode electrode 31 and the first cathode electrode 32, or at least a portion thereof.

For example, the second insulating layer PL2 may include silicon oxide (SiOx), silicon nitride (SiNₓ), silicon oxynitride (SiOₓN_{y}), silicon oxynitride (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like. These materials may be used alone or in combination with each other.

In one or more embodiments, the third insulating layer PL3 may cover the second inorganic light-emitting element LC2. For example, the third insulating layer PL3 may cover side surface of each of the first semiconductor layer S4, the active layer S5, and the second semiconductor layer S6. In addition, the third insulating layer PL3 may cover an upper surface of the second semiconductor layer S6. In addition, the third insulating layer PL3 may extend to cover side surface of each of the third lower electrode 13 and the fourth lower electrode 14.

In one or more embodiments, the third insulating layer PL3 may extend to cover side surface of each of the third adhesive member 23 and the fourth adhesive member 24. In one or more embodiments, the third insulating layer PL3 may extend to cover each of the third anode electrode 35 and the third cathode electrode 36, or at least a portion thereof.

For example, the third insulating layer PL3 may include silicon oxide (SiOx), silicon nitride (SiNₓ), silicon oxynitride (SiOₓN_{y}), silicon oxynitride (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like. These materials may be used alone or in combination with each other.

A second cathode electrode 15′ may be located in the first auxiliary pixel area SPX1, in the second auxiliary pixel area SPX2, and in the fourth auxiliary pixel area SPX4. That is, the second cathode electrode 15′ may be located on the first inorganic light-emitting element LC1, the organic light-emitting layer EML1, and the second inorganic light-emitting element LC2.

In one or more embodiments, the second cathode electrode 15′ may be continuously located over the first auxiliary pixel area SPX1, the second auxiliary pixel area SPX2, and the fourth auxiliary pixel area SPX4. That is, the second cathode electrode 15′ may be continuously located on the first inorganic light-emitting element LC1, the organic light-emitting layer EML1, the second inorganic light-emitting element LC2, and the pixel-defining layer PDL.

In this case, the light-emitting element LED may include a portion of the second cathode electrode 15′, the second anode electrode 33, and the organic light-emitting layer EML1. The portion of the second cathode electrode 15′ may be located in the second auxiliary pixel area SPX2.

The second cathode electrode 15′ may be spaced apart from the first inorganic light-emitting element LC1 with the second insulating layer PL2 interposed therebetween. In addition, the second cathode electrode 15′ may be spaced apart from the first adhesive member 21 and the second adhesive member 22 with the second insulating layer PL2 interposed therebetween. In addition, the second cathode electrode 15′ may be spaced apart from the first anode electrode 31 and the first cathode electrode 32 with the second insulating layer PL2 interposed therebetween.

In one or more embodiments, the second cathode electrode 15′ may be connected to a second connection electrode near a boundary line between the display area (e.g., the display area DA of FIG. 1) and the non-display area (NDA of FIG. 1). A power supply voltage may be applied to the second cathode electrode 15′ through the second connection electrode. For example, a low power supply voltage, such as ELVSS may be applied to the second cathode electrode 15′ through the second connection electrode. However, this disclosure is not limited thereto, and a position at which the second cathode electrode 15′ and the second connection electrode are connected may be changed.

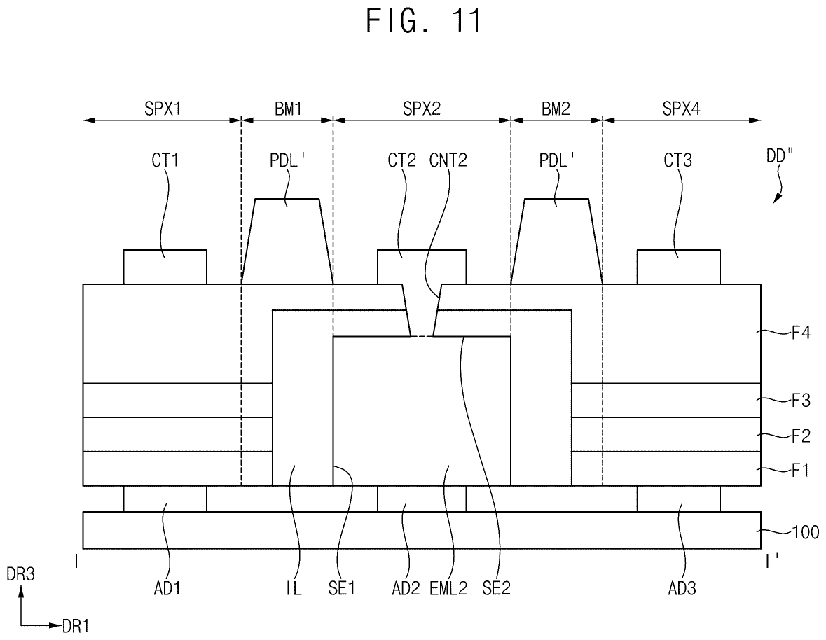

FIG. 11 is a cross-sectional view illustrating another example of the display device of FIG. 1 taken along the line I-I′.

Referring to FIGS. 1 and 11, a display device DD″ according to one or more other embodiments may include a substrate 100, a transparent electrode F1, a first semiconductor layer F2, an active layer F3, a second semiconductor layer F4, a first anode electrode AD1, a second anode electrode AD2, a third anode electrode AD3, a first cathode electrode CT1, a second cathode electrode CT2, a third cathode electrode CT3, an organic light-emitting layer EML2, an insulating layer IL, and a pixel-defining layer PDL′.

The first anode electrode AD1, the second anode electrode AD2, and the third anode electrode AD3 may be located on the substrate 100. The first anode electrode AD1 may be located in the first auxiliary pixel area SPX1. For example, the first anode electrode AD1 may include a metal, an alloy, a metal nitride, a conductive metal oxide, a transparent conductive material, or the like. These materials may be used alone or in combination with each other.

The second anode electrode AD2 may be located in the second auxiliary pixel area SPX2. That is, the second anode electrode AD2 may be spaced apart from the first anode electrode AD1 in the first direction DR1. For example, the second anode electrode AD2 may include a metal, an alloy, a metal nitride, a conductive metal oxide, a transparent conductive material, or the like. These materials may be used alone or in combination with each other.

The third anode electrode AD3 may be located in the fourth auxiliary pixel area SPX4. That is, the third anode electrode AD3 may be spaced apart from the second anode electrode AD2 in the first direction DR1. For example, the third anode electrode AD3 may include a metal, an alloy, a metal nitride, a conductive metal oxide, a transparent conductive material, or the like. These materials may be used alone or in combination with each other.

The transparent electrode F1 may be located on the first anode electrode AD1 and the third anode electrode AD3. The transparent electrode F1 may be located in the first auxiliary pixel area SPX1 and the fourth auxiliary pixel area SPX4. The transparent electrode F1 may be omitted from the second auxiliary pixel area SPX2. For example, the transparent electrode F1 may include ITO, IZO, IGO, AZO, or the like. These materials may be used alone or in combination with each other.

The first semiconductor layer F2 may be located on the transparent electrode F1. The first semiconductor layer F2 may be located in the first auxiliary pixel area SPX1 and the fourth auxiliary pixel area SPX4. The first semiconductor layer F2 may be omitted from the second auxiliary pixel area SPX2.

In one or more embodiments, the first semiconductor layer F2 may include a p-type semiconductor layer. For example, the first semiconductor layer F2 may include a semiconductor material, such as GaN, InAlGaN, AlGaN, InGaN, AlN, InN, or the like, and may include a p-type semiconductor layer doped with a first conductive dopant (e.g., a p-type dopant), such as Zn, Fe, Mg, Be, Cd, Ag, C, Hg, Li, Ca, or the like. For example, the first semiconductor layer F2 may include a GaN semiconductor material doped with the first conductive dopant.

The active layer F3 may be located on the first semiconductor layer F2. The active layer F3 may be located on the first semiconductor layer F2. The active layer F3 may be located in the first auxiliary pixel area SPX1 and the fourth auxiliary pixel area SPX4. The active layer F3 may be omitted from the second auxiliary pixel area SPX2.

For example, the active layer F3 may include a single-well structure, a multi-well structure, a single-quantum well structure, a multi-quantum well structure, a quantum dot structure, or a quantum wire structure. For example, the active layer F3 may include a multi-quantum well structure. In this case, the active layer F3 may include a structure in which well layers and barrier layers are alternately stacked. The well layer may include InGaN, and the barrier layer may include GaN or AlGaN, but this disclosure is not limited thereto.

The second semiconductor layer F4 may be located on the active layer F3. The second semiconductor layer F4 may be located in the first auxiliary pixel area SPX1, the second auxiliary pixel area SPX2, and the fourth auxiliary pixel area SPX4. In one or more embodiments, the second semiconductor layer F4 may be continuously located over the first auxiliary pixel area SPX1, the second auxiliary pixel area SPX2, and the fourth auxiliary pixel area SPX4.

In one or more embodiments, the second semiconductor layer F4 may include an n-type semiconductor layer. For example, the second semiconductor layer F4 may include a semiconductor material, such as GaN, InAlGaN, AlGaN, InGaN, AlN, InN, or the like, and may include an n-type semiconductor layer doped with a second conductive dopant (e.g., an n-type dopant), such as Si, Sn, Te, Se, S, O, Ti, Ge, or the like. For example, the second semiconductor layer F4 may include a GaN semiconductor material doped with the second conductive dopant. However, this disclosure is not limited thereto, and in one or more other embodiments, the first semiconductor layer F2 may include an n-type semiconductor layer, and the second semiconductor layer F4 may include a p-type semiconductor layer.

In addition, in one or more embodiments, an undoped semiconductor layer may be further located on the second semiconductor layer F4. The undoped semiconductor layer may include GaN.

The first cathode electrode CT1 may be located on the second semiconductor layer F4. The first cathode electrode CT1 may be located in the first auxiliary pixel area SPX1. For example, the first cathode electrode CT1 may include a metal, an alloy, a metal nitride, a conductive metal oxide, a transparent conductive material, or the like. These materials may be used alone or in combination with each other.

The second cathode electrode CT2 may be located on the second semiconductor layer F4. The second cathode electrode CT2 may be located in the second auxiliary pixel area SPX2. That is, the second cathode electrode CT2 may be spaced apart from the first cathode electrode CT1 in the first direction DR1. The second cathode electrode CT2 may be electrically connected to the organic light-emitting layer EML2 through a contact hole CNT2. The contact hole CNT2 may be defined through the second semiconductor layer F4 and the insulating layer IL. For example, the second cathode electrode CT2 may include a metal, an alloy, a metal nitride, a conductive metal oxide, a transparent conductive material, or the like. These materials may be used alone or in combination with each other.

The third cathode electrode CT3 may be located on the second semiconductor layer F4. The third cathode electrode CT3 may be located in the fourth auxiliary pixel area SPX4. That is, the third cathode electrode CT3 may be spaced apart from the second cathode electrode CT2 in the first direction DR1. For example, the third cathode electrode CT3 may include a metal, an alloy, a metal nitride, a conductive metal oxide, a transparent conductive material, or the like. These materials may be used alone or in combination with each other.

The pixel-defining layer PDL′ may be located on the second semiconductor layer F4. For example, the pixel-defining layer PDL′ may have a shape surrounding the second auxiliary pixel area SPX2 in the plan view. The pixel-defining layer PDL′ may have or define an opening overlapping the second auxiliary pixel area SPX2 in the plan view. The second cathode electrode CT2 may be located in the opening of the pixel-defining layer PDL′.

As shown in FIG. 11, a first portion of the pixel-defining layer PDL′ may be located in a first non-light-emitting area BM1. That is, the first portion of the pixel-defining layer PDL′ may be located between the first auxiliary pixel area SPX1 and the second auxiliary pixel area SPX2. In addition, a second portion of the pixel-defining layer PDL′ may be located in the second non-light-emitting area BM2. That is, the second portion of the pixel-defining layer PDL′ may be located between the second auxiliary pixel area SPX2 and the fourth auxiliary pixel area SPX4.

For example, the pixel-defining layer PDL′ may include an inorganic material or an organic material. In one or more embodiments, the pixel-defining layer PDL′ may include an organic material, such as an epoxy resin, a siloxane resin, or the like. These materials may be used alone or in combination with each other. In one or more other embodiments, the pixel-defining layer PDL′ may further include a light-blocking material containing a black pigment, a black dye, or the like.

The organic light-emitting layer EML2 may be located in the second auxiliary pixel area SPX2. In one or more embodiments, the organic light-emitting layer EML2 may penetrate the transparent electrode F1, the first semiconductor layer F2, and the active layer F3. In one or more embodiments, the organic light-emitting layer EML2 may further penetrate at least a portion of the second semiconductor layer F4.

However, this disclosure is not limited thereto, and in one or more other embodiments, the organic light-emitting layer EML2 may not penetrate the second semiconductor layer F4. For example, the organic light-emitting layer EML2 may include an organic material that emits light of a color (e.g., a predetermined color).

The insulating layer IL may cover the organic light-emitting layer EML2. In detail, the insulating layer IL may cover a side surface SE1 and an upper surface SE2 of the organic light-emitting layer EML2. The upper surface SE2 of the organic light-emitting layer EML2 may be a surface facing the second cathode electrode CT2.

The insulating layer IL may be located in a portion of the first non-light-emitting rea BM1. In addition, the insulating layer IL may be located in a portion of the second non-light-emitting area BM2. In addition, the insulating layer IL may be located in the second auxiliary pixel area SPX2.

For example, the insulating layer IL may include silicon oxide (SiOx), silicon nitride (SiNₓ), silicon oxynitride (SiOₓN_{y}), silicon oxynitride (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like. These materials may be used alone or in combination with each other.

In one or more embodiments, the organic light-emitting layer EML2 may emit red light. That is, red light may be emitted from the second auxiliary pixel area SPX2. That is, by using the organic light-emitting layer EML2 including an organic material with respect to red light, light-emitting efficiency of the red light may be improved.

In this case, blue light may be emitted from the first auxiliary pixel area SPX1, and green light may be emitted from the third auxiliary pixel area SPX3. Alternatively, green light may be emitted from the first auxiliary pixel area SPX1, and blue light may be emitted from the third auxiliary pixel area SPX3.

However, this disclosure is not limited thereto, and in one or more other embodiments, the organic light-emitting layer EML2 may emit green light. In this case, a second organic light-emitting layer having substantially the same structure as the organic light-emitting layer EML2 may be located in the third auxiliary pixel area SPX3. The second organic light-emitting layer may emit red light. That is, green light may be emitted in the second auxiliary pixel area SPX2, and red light may be emitted in the third auxiliary pixel area SPX3.

That is, with respect to the green light and the red light, light-emitting efficiency of each of the green light and the red light may be improved by using the organic light-emitting layer EML2 and the second organic light-emitting layer. In this case, the blue light may be emitted from the first auxiliary pixel area SPX1.

Alternatively, the organic light-emitting layer EML2 may emit red light, and the second organic light-emitting layer may emit green light. That is, blue light may be emitted from the first auxiliary pixel area SPX1, red light may be emitted from the second auxiliary pixel area SPX2, and green light may be emitted from the third auxiliary pixel area SPX3.

Although the first pixel area PX1 including the first auxiliary pixel area SPX1, the second auxiliary pixel area SPX2, and the third auxiliary pixel area SPX3 has been described with reference to FIGS. 1 and 11, this disclosure is not limited thereto, and the second pixel area PX2 and the first pixel area PX1 may also include substantially the same structure.

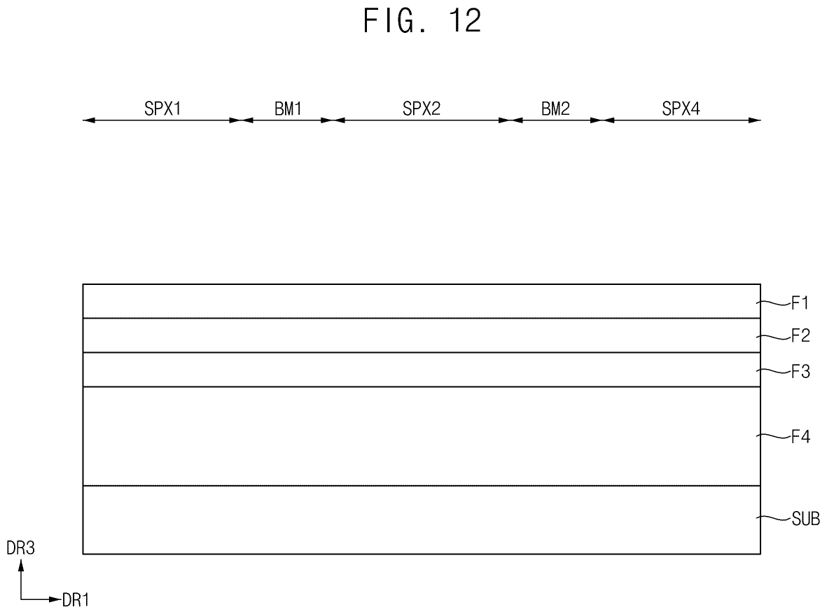

FIGS. 12, 13, 14, 15, 16, 17, 18, and 19 are cross-sectional views illustrating a method of manufacturing the display device of FIG. 11.

Referring to FIG. 12, the second semiconductor layer F4 may be formed on a growth substrate SUB. The growth substrate SUB may be an epitaxial substrate. For example, the epitaxial substrate may include a silicon substrate, a sapphire substrate, and/or the like. The second semiconductor layer F4 may be formed by an epitaxial growth method.

In one or more embodiments, the second semiconductor layer F4 may include an n-type semiconductor layer. For example, the second semiconductor layer F4 may include a semiconductor material, such as GaN, InAlGaN, AlGaN, InGaN, AlN, InN, or the like, and may include an n-type semiconductor layer doped with a second conductive dopant (e.g., an n-type dopant), such as Si, Sn, Te, Se, S, O, Ti, Ge, or the like. For example, the second semiconductor layer F4 may include a GaN semiconductor material doped with the second conductive dopant.

The active layer F3 may be located on the second semiconductor layer F4. The active layer F3 may be formed by an epitaxial growth method. For example, the active layer F3 may include a single-well structure, a multi-well structure, a single-quantum well structure, a multi-quantum well structure, a quantum dot structure, or a quantum wire structure. For example, the active layer F3 may include a multi-quantum well structure. In this case, the active layer F3 may include a structure in which well layers and barrier layers are alternately stacked. The well layer may include InGaN, and the barrier layer may include GaN or AlGaN, but this disclosure is not limited thereto.

The first semiconductor layer F2 may be formed on the active layer F3. The first semiconductor layer F2 may be formed by an epitaxial growth method. For example, the first semiconductor layer F2 may include a semiconductor material, such as GaN, InAlGaN, AlGaN, InGaN, AlN, InN, or the like, and may include a p-type semiconductor layer doped with a first conductive dopant (e.g., a p-type dopant), such as Zn, Fe, Mg, Be, Cd, Ag, C, Hg, Li, Ca, or the like. For example, the first semiconductor layer F2 may include a GaN semiconductor material doped with the first conductive dopant.

The transparent electrode F1 may be formed on the first semiconductor layer F2. For example, the transparent electrode F1 may include ITO, IZO, IGO, AZO, or the like. These materials may be used alone or in combination with each other.

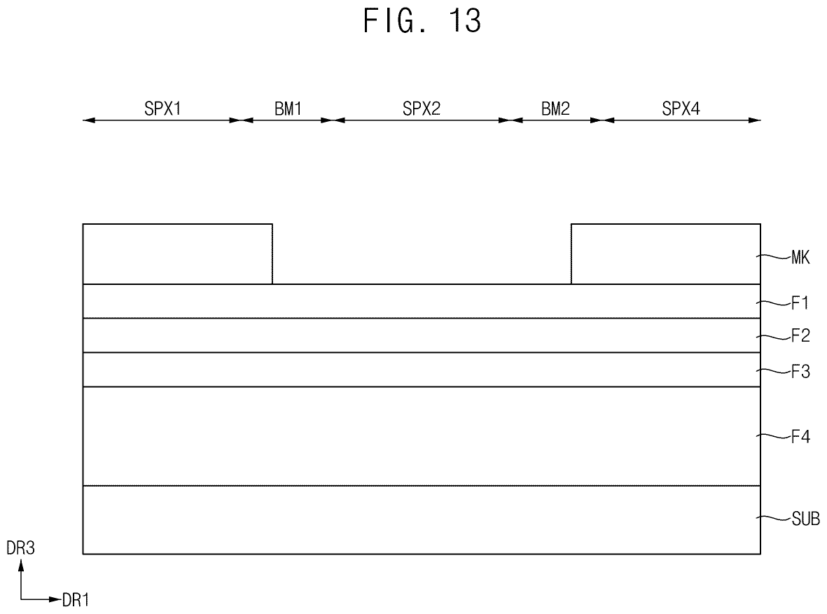

Referring to FIG. 13, a mask MK may be formed on the transparent electrode F1. The mask MK may be formed in the first auxiliary pixel area SPX1 and the fourth auxiliary pixel area SPX4. In addition, the mask MK may be formed on a portion of the first non-light-emitting area BM1. In addition, the mask MK may be formed on a portion of the second non-light-emitting area BM2.

For example, the mask MK may include silicon nitride, silicon dioxide, silicon oxide, or the like. These materials may be used alone or in combination with each other.

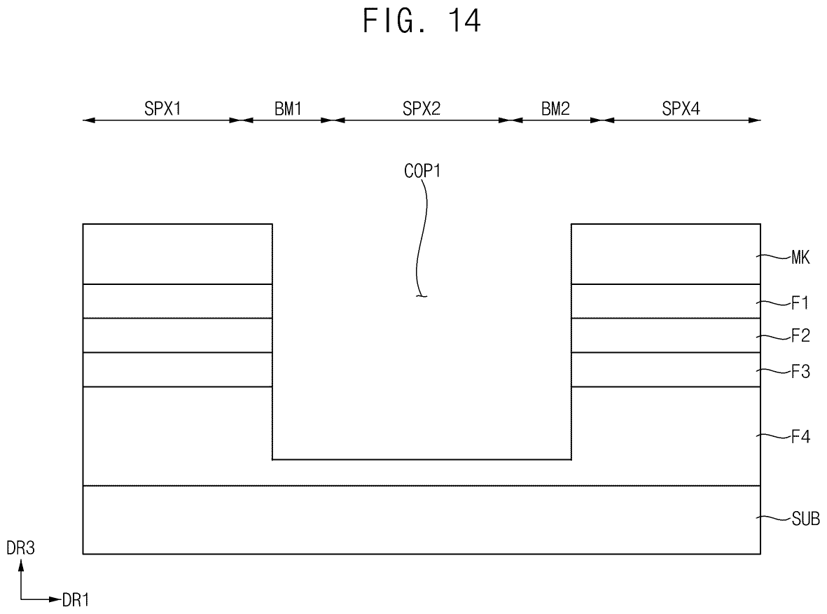

Referring to FIG. 14, a first opening COP1 may be formed in a portion that does not overlap the mask MK in the plan view. The first opening COP1 may be formed in the second auxiliary pixel area SPX2. In addition, the first opening COP1 may be formed in a portion of the first non-light-emitting area BM1. In addition, the first opening COP1 may be formed in a portion of the second non-light-emitting area BM2. For example, the first opening COP1 may be formed through an etching process. The first opening COP1 may be defined through the transparent electrode F1, the first semiconductor layer F2, and the active layer F3. In addition, the first opening COP1 may further be defined through at least a portion of the second semiconductor layer F4.

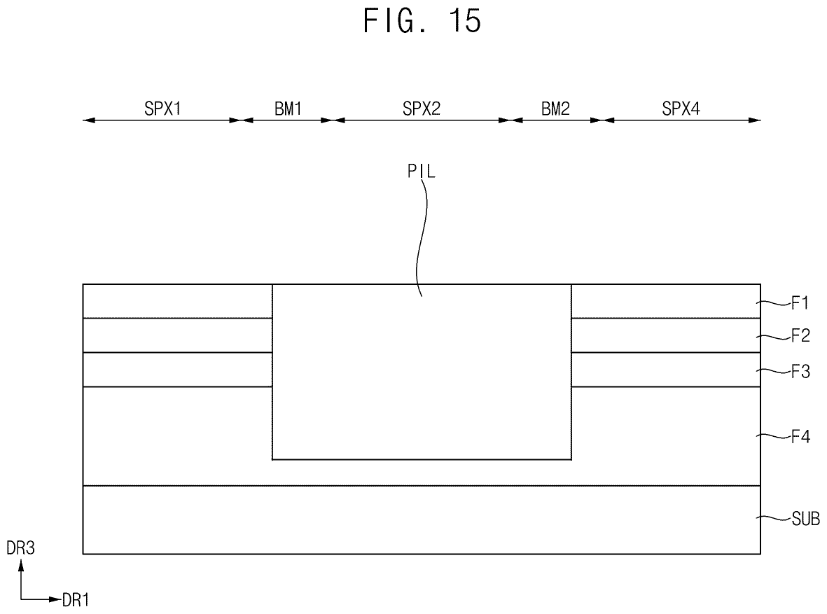

Referring to FIG. 15, the preliminary insulating layer PIL may fill the first opening COP1. For example, the preliminary insulating layer PIL may include silicon oxide (SiOx), silicon nitride (SiNₓ), silicon oxynitride (SiOₓN_{y}), silicon oxynitride (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like. These materials may be used alone or in combination with each other.

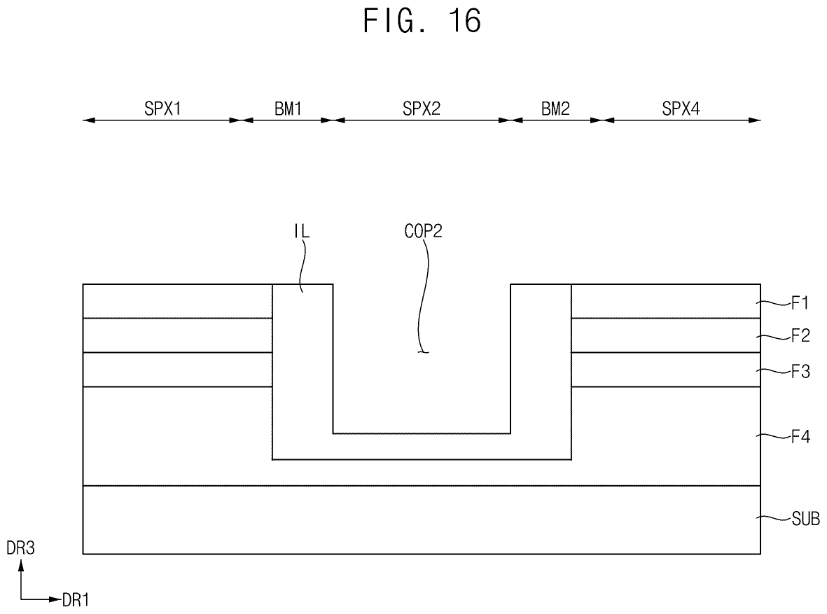

Referring to FIGS. 15 and 16, a second opening COP2 may be formed in the preliminary insulating layer PIL. Accordingly, the insulating layer IL may be formed. The second opening COP2 may be formed in the second auxiliary pixel area SPX2. The second opening COP2 may be formed in substantially the same manner as the method in which the first opening COP1 is formed.

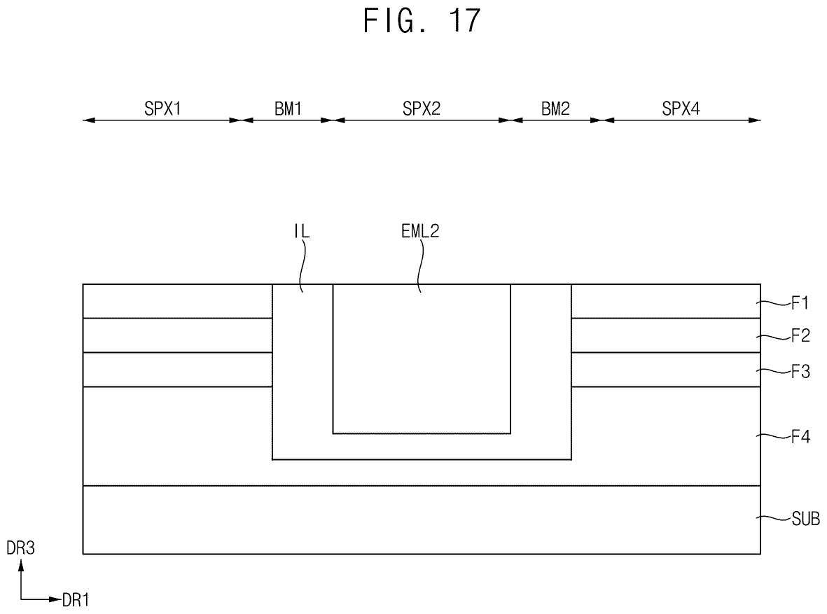

Referring to FIG. 17, the organic light-emitting layer EML2 may fill the second opening COP2. For example, the organic light-emitting layer EML2 may include an organic material for emitting light of a color (e.g., a predetermined color).

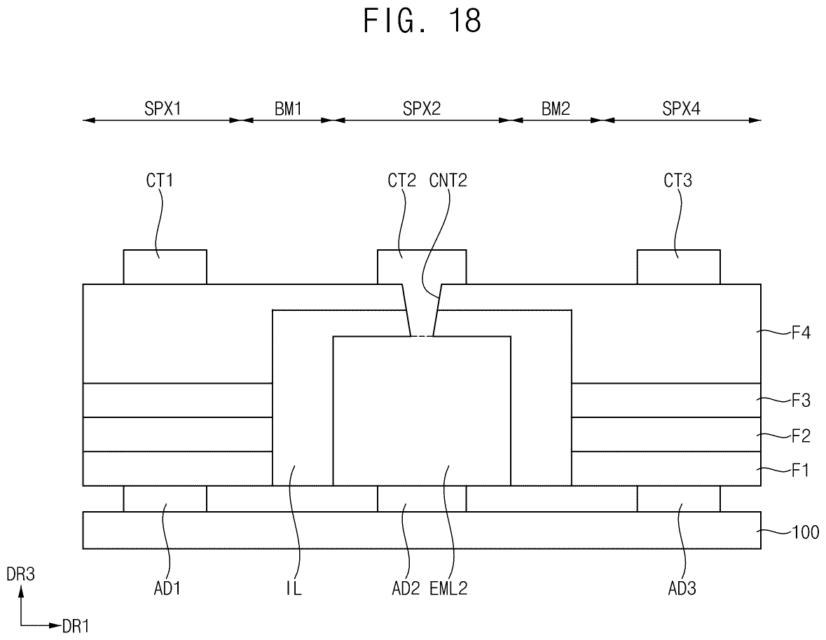

Referring to FIGS. 17 and 18, the first anode electrode AD1, the second anode electrode AD2, and the third anode electrode AD3 may be formed on the substrate 100. The first anode electrode AD1 may be formed in a portion of the first auxiliary pixel area SPX1. The second anode electrode AD2 may be formed in a portion of the second auxiliary pixel area SPX2. The third anode electrode AD3 may be formed in a portion of the fourth auxiliary pixel area SPX4.

For example, each of the first anode electrode AD1, the second anode electrode AD2, and the third anode electrode AD3 may include a metal, an alloy, a metal nitride, a conductive metal oxide, a transparent conductive material, or the like. These materials may be used alone or in combination with each other.

The growth substrate SUB may be removed by laser lift-off (LLO), and/or the like. The transparent electrode F1 may be attached to the first anode electrode AD1 and to the third anode electrode AD3. In addition, the organic light-emitting layer EML2 may be attached to the second anode electrode AD2. That is, the transparent electrode F1, the first semiconductor layer F2, the active layer F3, the second semiconductor layer F4, the organic light-emitting layer EML2, and the insulating layer IL may be transferred to the substrate 100.

The first cathode electrode CT1, the second cathode electrode CT2, and the third cathode electrode CT3 may be formed on the second semiconductor layer F4. The first cathode electrode CT1 may be formed in a portion of the first auxiliary pixel area SPX1. The second cathode electrode CT2 may be formed in a portion of the second auxiliary pixel area SPX2. The third cathode electrode CT3 may be formed in a portion of the fourth auxiliary pixel area SPX4.

For example, each of the first cathode electrode CT1, the second cathode electrode CT2, and the third cathode electrode CT3 may include a metal, an alloy, a metal nitride, a conductive metal oxide, a transparent conductive material, or the like. These materials may be used alone or in combination with each other.

The contact hole CNT2 may be defined through the second semiconductor layer F4 and the insulating layer IL. The second cathode electrode CT2 may be connected to the organic light-emitting layer EML2 through the contact hole CNT2.

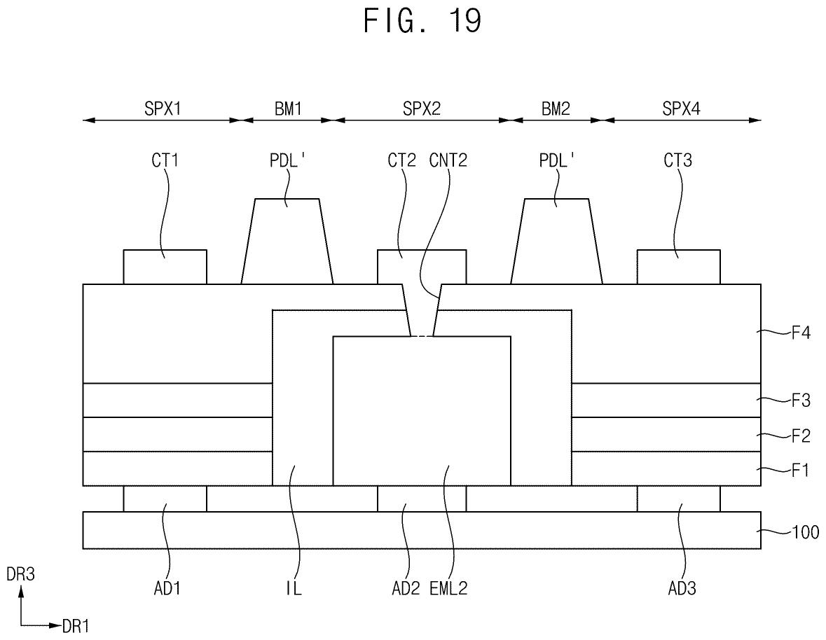

Referring to FIG. 19, the pixel-defining layer PDL′ may be formed on the second semiconductor layer F4. The pixel-defining layer PDL′ may surround the second auxiliary pixel area SPX2 in the plan view.

For example, a first portion of the pixel-defining layer PDL′ may be formed in the first non-light-emitting area BM1. That is, the first portion of the pixel-defining layer PDL′ may be formed between the first auxiliary pixel area SPX1 and the second auxiliary pixel area SPX2. In addition, a second portion of the pixel-defining layer PDL′ may be formed in the second non-light-emitting area BM2. That is, the second portion of the pixel-defining layer PDL′ may be formed between the second auxiliary pixel area SPX2 and the fourth auxiliary pixel area SPX4.

For example, the pixel-defining layer PDL′ may include an inorganic material or an organic material. In one or more embodiments, the pixel-defining layer PDL′ may include an organic material, such as an epoxy resin, a siloxane resin, or the like. These materials may be used alone or in combination with each other. In one or more other embodiments, the pixel-defining layer PDL′ may further include a light-blocking material containing a black pigment, a black dye, or the like.

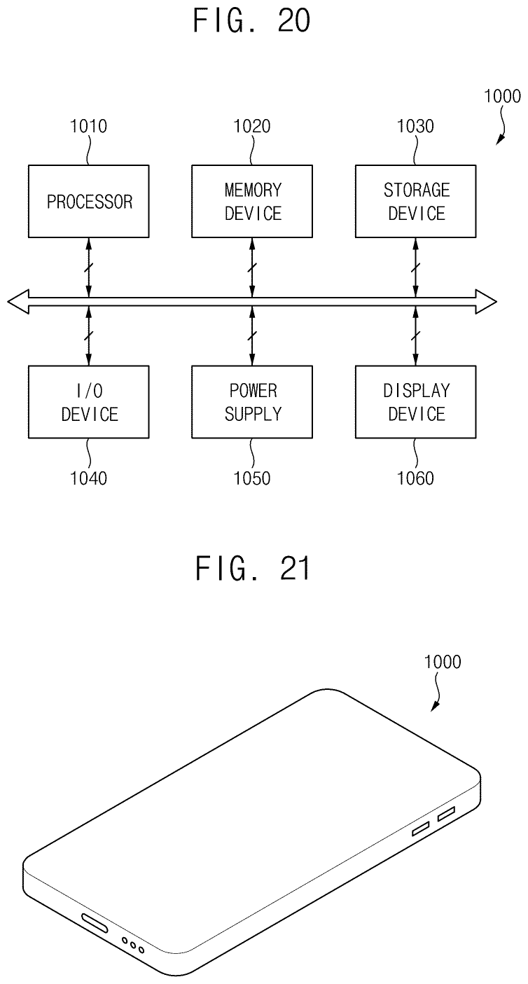

FIG. 20 is a block diagram illustrating an electronic device according to embodiments. FIG. 21 is a diagram illustrating an example in which the electronic device of FIG. 20 is implemented as a smart phone.

Referring to FIGS. 20 and 21, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 21, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

The present disclosure can be applied to various display devices. For example, the present disclosure is applicable to various display devices, such as display devices for vehicles, ships and aircraft, portable communication devices, display devices for exhibition or information transmission, medical display devices, and/or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the embodiments disclosed, and that modifications to the disclosed embodiments, as well as other embodiments, are intended to be included within the scope of the appended claims.

What is claimed is:

1. A display device comprising:
a first electrode above a substrate;
a second electrode above the substrate, and spaced apart from the first electrode in a first direction;
an inorganic light-emitting element in a first auxiliary pixel area, above the first electrode, and connected to the first electrode;
an organic light-emitting layer above the substrate, in a second auxiliary pixel area spaced apart from the first auxiliary pixel area in the first direction, and covering the second electrode; and
a third electrode above the organic light-emitting layer.

2. The display device of claim 1, wherein the third electrode is spaced apart from the inorganic light-emitting element in plan view.

3. The display device of claim 2, further comprising a connection electrode above the substrate, in a portion of the second auxiliary pixel area, configured to receive a low power supply voltage, and connected to the third electrode.

4. The display device of claim 3, wherein the connection electrode at least partially overlaps the third electrode in plan view.

5. The display device of claim 2, further comprising a fourth electrode in a portion of the first auxiliary pixel area, above the substrate, and connected to the inorganic light-emitting element.

6. The display device of claim 5, wherein the fourth electrode is spaced apart from the third electrode in plan view.

7. The display device of claim 1, further comprising a pixel-defining layer above the substrate, surrounding the second auxiliary pixel area in plan view, and spaced apart from the third electrode in plan view.

8. The display device of claim 1, wherein a portion of the third electrode is above the organic light-emitting layer, and another portion of the third electrode is above the inorganic light-emitting element.

9. The display device of claim 8, wherein the third electrode at least partially overlaps the inorganic light-emitting element in plan view.

10. The display device of claim 8, wherein the third electrode is continuously over the first auxiliary pixel area and the second auxiliary pixel area.

11. The display device of claim 8, wherein the inorganic light-emitting element comprises a first semiconductor layer, an active layer above the first semiconductor layer, and a second semiconductor layer above the active layer.

12. The display device of claim 11, further comprising an insulating layer covering both sides of the first semiconductor layer, both sides of the active layer, both sides of the second semiconductor layer, and an upper surface of the second semiconductor layer.

13. The display device of claim 12, wherein the third electrode is spaced apart from the inorganic light-emitting element with the insulating layer therebetween.

14. The display device of claim 1, further comprising a fourth electrode in a portion of the first auxiliary pixel area, above the substrate, connected to the inorganic light-emitting element, and covered by the insulating layer.

15. The display device of claim 14, wherein the third electrode is spaced apart from the fourth electrode with the insulating layer therebetween.

16. The display device of claim 8, further comprising a pixel-defining layer above the substrate, surrounding the second auxiliary pixel area in plan view, and covered by the third electrode.

17. The display device of claim 1, wherein the organic light-emitting layer is configured to emit green light or red light.

18. A method of manufacturing a display device, the method comprising:
forming a first electrode above a substrate;
forming a second electrode spaced apart from the first electrode in a first direction above the substrate;
bonding the first electrode and an inorganic light-emitting element;
forming an organic light-emitting layer covering the second electrode; and
forming a third electrode spaced apart from the inorganic light-emitting element in plan view above the organic light-emitting layer.

19. The method of claim 18, wherein the bonding the first electrode and the inorganic light-emitting element is performed before the forming the organic light-emitting layer.

20. The method of claim 18, further comprising forming a contact hole connecting the third electrode and a connection electrode above the substrate,
wherein the connection electrode is configured to be applied with a low power supply voltage.

21. An electronic device comprising:
a first electrode above a substrate;
a second electrode above the substrate, and spaced apart from the first electrode in a first direction;
an inorganic light-emitting element in a first auxiliary pixel area, above the first electrode, and connected to the first electrode;
an organic light-emitting layer above the substrate, in a second auxiliary pixel area spaced apart from the first auxiliary pixel area in the first direction, and covering the second electrode;
a third electrode above the organic light-emitting layer; and
a memory device configured to store data.
